(19) United States
(12) Patent Application Publication
(10) Pub. No.: US 2019/0280013 A1
(43) Pub. Date: Sep. 12, 2019

(54) ACTIVE MATRIX SUBSTRATE AND DISPLAY PANEL

(71) Applicant: SHARP KABUSHIKI KAISHA, Sakai City (JP)

(72) Inventor: YOHSUKE FUJIKAWA, Sakai City (JP)

(21) Appl. No.: 16/293,303

(22) Filed: Mar. 5, 2019

(30) Foreign Application Priority Data
Mar. 6, 2018 (JP) 2018-039746

(51) Int. Cl. H01L 27/12

(52) U.S. Cl. CPC H01L 27/124; H01L 27/3276

(57) ABSTRACT

To enhance the degree of freedom in configuration so as to suppress electrostatic breakdown. An array substrate is provided with: pixels; a source wiring; a panel side input terminal part; a second wiring; a second low resistance wiring part connected to the source wiring or the panel side input terminal part; a second high resistance wiring part which is connected to the panel side input terminal part or the source wiring and whose ratio of a wiring length occupied in the second wiring is higher than that of the second low resistance wiring part, and a second connection part that connects the second low resistance wiring part and the second high resistance wiring part with each other.

### CROSS REFERENCE TO RELATED APPLICATION

This application claims priority from Japanese Patent Application No. 2018-039746 filed on Mar. 6, 2018. The entire contents of the priority application are incorporated herein by reference.

### TECHNICAL FIELD

The technology described herein relates to an active matrix substrate and a display panel.

### BACKGROUND

An image display device may include wirings that are formed on a substrate to be parallel to one another. The wirings connect two among an external connection terminal, a driving IC and a display part with each other. Each of the plural wirings is provided with a plurality of conductor layers formed on different planes and contact hole conductors that mutually connect the plural conductor layers electrically. The mutually adjacent wirings are formed so that the conductor layers formed on mutually different planes are formed so as to be adjacent to one another.

Another display device may be provided with first and second wiring parts and a plurality of signal lines having inside connection parts that connect the first and second wiring parts with each other. The first and second signal wiring parts of one of two adjacent signal lines are constituted by first and second conductive layers, and the first and second signal wiring parts of the other signal line are constituted by first and second conductive layers of the first and second conductive layers, respectively. Moreover, each of the plural signal lines has its position of the connection part of the corresponding signal line determined based upon the wiring position in the wiring area of the signal line.

### SUMMARY

In accordance with the display device described in the above-mentioned Patent Literature 1, since the lengths of the respective conductor layers of the adjacent wirings are set to be substantially the same, resistance between the adjacent wirings can be made uniform even when sheet resistance between the respective conductor layers is different. Moreover, in accordance with the display device described in the above-mentioned Patent Literature 2, among a plurality of the respective signal lines, positions of the connection parts are determined so as to make the lengths of the first and second wiring parts equal to each other so that the same effect as that of Patent Literature 1 can be obtained. Since these Patent Literatures 1 and 2 have configurations in which the lengths of the respective conductor layers of wirings and the lengths of the first and second wiring parts are made equal, wiring resistance tends to become lower when the wiring length of a wiring and a signal line becomes shorter although the wiring resistance becomes uniform when the wiring lengths of the wiring and signal line are the same. For this reason, in the case when an ESD (Electro-Static Discharge) is inputted to a wiring or a signal line whose wiring length is short, an electrostatic breakdown might occur in a pixel or the like connected to the wiring or the signal line. Since the above-mentioned Patent Literatures 1 and 2 are characterized by a configuration in which the lengths of the respective conductor layers of wirings and the first and second wiring parts are made equal to each other, the degree of freedom for altering the configurations of the wirings and signal lines is poor, with the result that it has been difficult to take measures for suppressing a dielectric breakdown.

The present invention has been completed in view of the above-mentioned circumstances, and its object is to enhance the degree of freedom for the configuration and consequently to suppress the electrostatic breakdown.

An active matrix substrate in accordance with the present invention is provided with: pixels; pixel wirings that are connected with the pixels; a signal input part for use in inputting a signal to the above-mentioned pixel wiring; wirings connected to the pixel wiring and the signal input part; a low resistance wiring part that constitutes the wiring and has its one end side connected to the pixel wiring or the signal input part; a high resistance wiring part that constitutes the wiring and has its one end side connected to the signal input part or the pixel wiring and also has resistance higher than that of the low resistance wiring part, with a ratio of the wiring length of the high resistance wiring part occupied in the above-mentioned wiring being made higher than the corresponding ratio of the above-mentioned low resistance wiring part; and a connection part that mutually connects the other ends of the above-mentioned low resistance wiring part and high resistance wiring part.

With this arrangement, a signal from the signal input part is transmitted to the pixel wiring through the wiring and then supplied to a pixel. Since the wiring has higher degree of freedom in configuration in comparison with the conventional one and since the ratio of the wiring length of the high resistance wiring part occupied in the wiring is higher than the corresponding ratio of the low resistance wiring part, it becomes possible to prevent the wiring resistance relating to the wiring from becoming too low, even when the wiring length of the entire wiring becomes shorter. Therefore, even in the case when an ESD is inputted to the wiring, it is possible to make an electrostatic breakdown hardly occur in the pixel or the like connected to the wiring through the pixel electrode. In the case when the electrostatic breakdown is made to hardly occur in the pixel or the like connected to the wiring through the pixel electrode, for example, it becomes not necessary to connect an ESD protection circuit to the wiring, and even in the case of, for example, connecting the ESD protection circuit, it is only necessary to use a simple small-size ESD protection circuit. Thus, since the layout space for the wiring can be reduced, it becomes possible to desirably achieve a narrower frame.

In accordance with the present invention, it becomes possible to enhance the degree of freedom in the configuration and consequently to suppress the electrostatic breakdown.

### BRIEF DESCRIPTION OF THE DRAWINGS

FIG. 1 is a plan view of a liquid crystal panel constituting a liquid crystal device relating to a first embodiment of the present invention.

FIG. 2 is a plan view showing a wiring configuration in an array substrate constituting the liquid crystal panel.

FIG. 3 is a plan view showing first wirings and second wirings in a wiring area of the array substrate.

FIG. 4 is a plan view that mainly shows the second wiring.

FIG. 5 is a cross-sectional view taken along line A-A of FIG. 3.

FIG. 6 is a cross-sectional view taken along line B-B of FIG. 3.

FIG. 7 is a cross-sectional view taken along line C-C of FIG. 3.

FIG. 8 is a cross-sectional view showing one of the second wirings (one of the first wirings) in the vicinity of a second connection part (first connection part).

FIG. 9 is a cross-sectional view showing the other second wiring (the other first wiring) in the vicinity of the second connection part (first connection part).

FIG. 10 is a plan view showing the first wirings.

FIG. 11 is a cross-sectional view taken along line D-D of FIG. 3.

FIG. 12 is a cross-sectional view taken along line E-E of FIG. 3.

FIG. 13 is a graph showing ratios of wiring lengths of a low resistance wiring part and a high resistance wiring part occupied in the wiring of the prior art.

FIG. 14 is a graph showing the wiring resistance of the wiring of the prior art.

FIG. 15 is a graph showing ratios of a low resistance wiring part and a high resistance wiring part occupied in each of the wirings of the present embodiment.

FIG. 16 is a graph showing the wiring resistance of each of the wiring of the present embodiment.

FIG. 17 is a plan view that mainly shows a second wiring in accordance with a second embodiment.

FIG. 18 is a plan view showing a first wiring and a second wiring in a wiring area of an array substrate in accordance with a third embodiment.

FIG. 19 is a plan view showing a first wiring.

FIG. 20 is a plan view showing a first wiring and a second wiring in a wiring area of an array substrate in accordance with a fourth embodiment.

FIG. 21 is a plan view that mainly shows the second wiring.

FIG. 22 shows a wiring configuration in an array substrate in accordance with another first embodiment.

FIG. 23 shows a wiring configuration in an array substrate in accordance with still another second embodiment.

FIG. 24 shows a wiring configuration in an array substrate in accordance with still another third embodiment.

FIG. 25 shows a wiring configuration in an array substrate in accordance with still another fourth embodiment.

FIG. 26 shows a wiring configuration in an array substrate in accordance with still another fifth embodiment.

FIG. 27 shows a wiring configuration in an array substrate in accordance with still another sixth embodiment.

FIG. 28 is a plan view showing a wiring configuration in an array substrate in accordance with still another seventh embodiment.

FIG. 29 is a plan view showing a wiring configuration in an array substrate in accordance with still another eighth embodiment.

FIG. 30 is a plan view showing a wiring configuration in an array substrate in accordance with still another ninth embodiment.

FIG. 31 is a plan view showing a liquid crystal panel in accordance with still another tenth embodiment.

FIG. 32 is a plan view showing a liquid crystal panel in accordance with the other eleventh embodiment.

### DETAILED DESCRIPTION

### First Embodiment

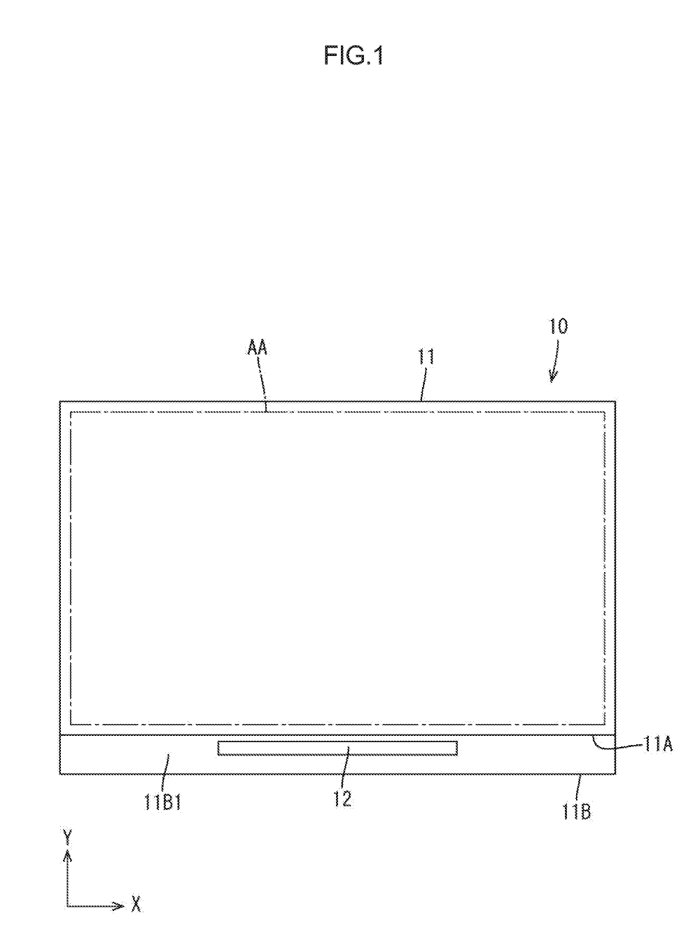

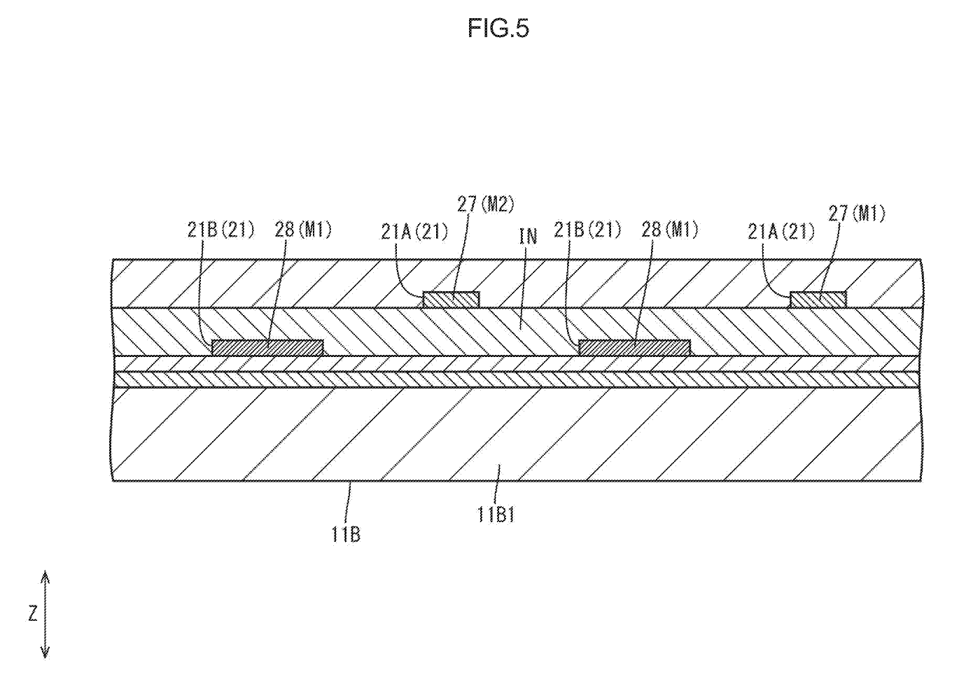

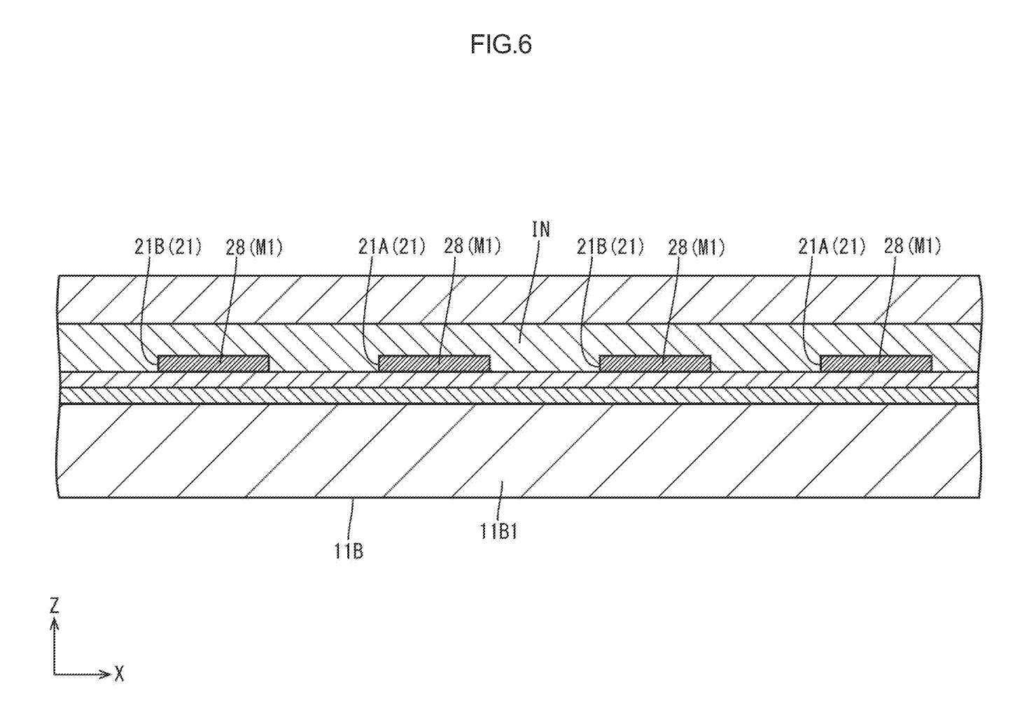

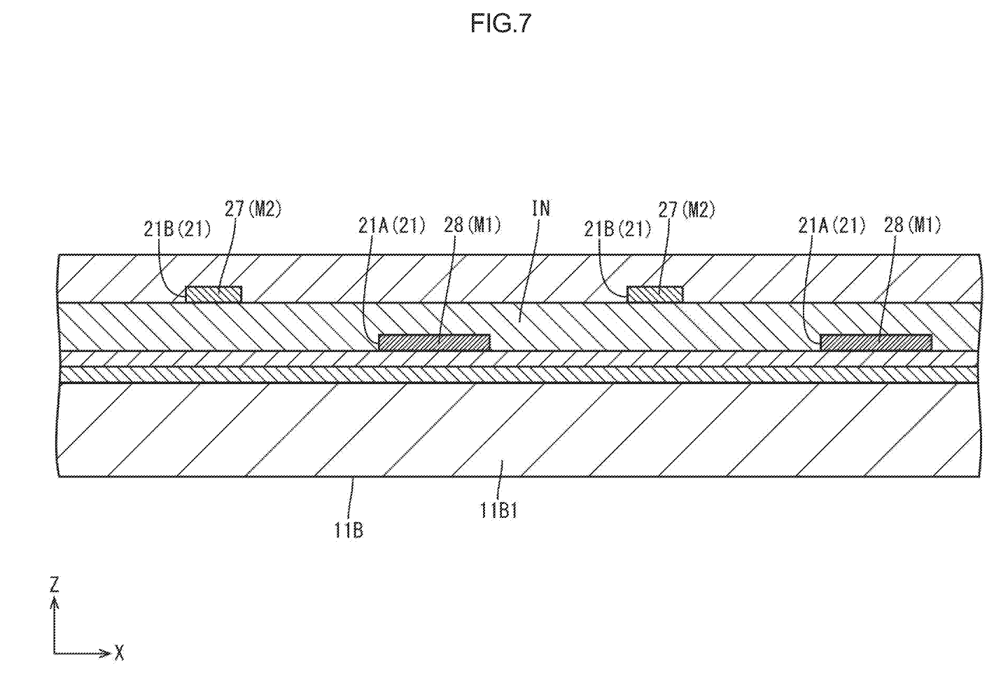

A first embodiment will be described with reference to FIGS. 1 to 16. In the present embodiment, a liquid crystal display device (display device) 10 is exemplified. Additionally, on one portion of each drawing, X-axis, Y-axis and Z-axis are indicated, and illustrations are given so that the respective axis directions correspond to directions shown in each drawing. Moreover, with respect to the vertical directions, based upon FIG. 5 or the like, the upper side of each of these drawings is defined as the surface side, and the lower side thereof is defined as the back surface side.

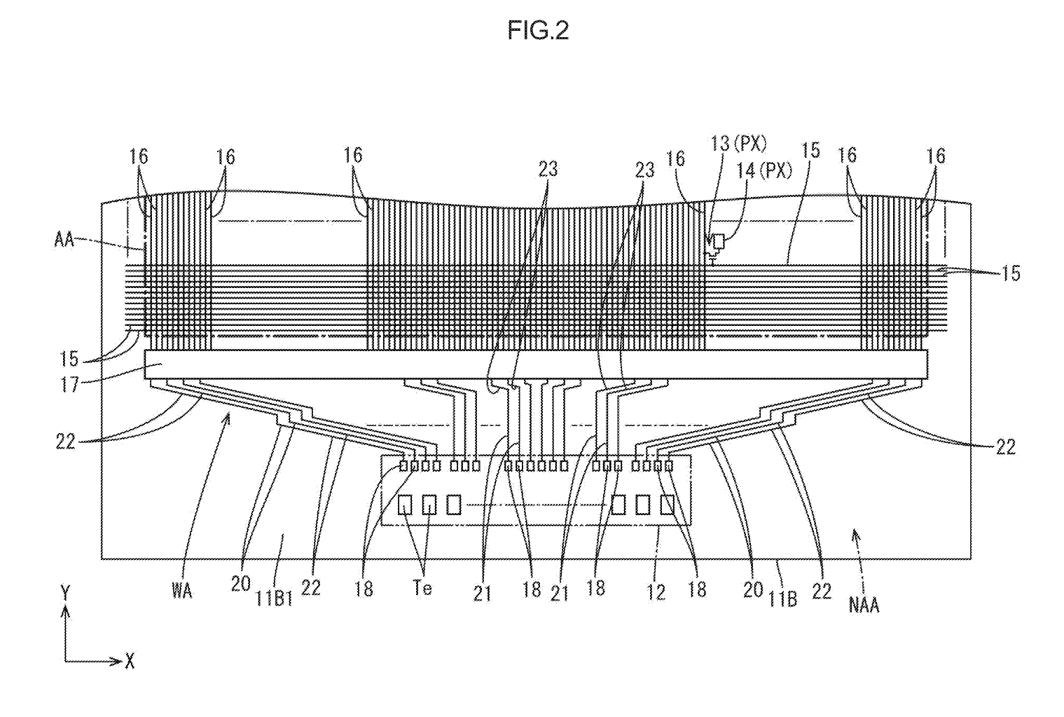

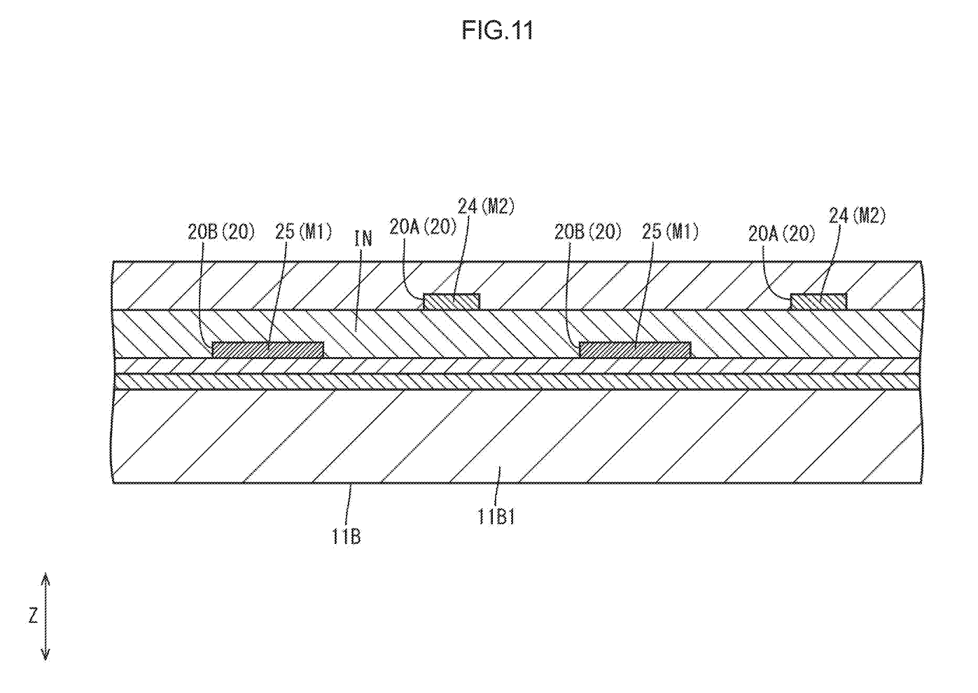

As shown in FIG. 11, the liquid crystal display device 10 is typically provided with a liquid crystal panel (electronic device, display panel) 11 capable of displaying images, and a back light device (lighting device), not shown, serving as an external light source for illuminating light for use in display to the liquid crystal display panel 11. The liquid crystal panel 11 has a rectangular shape in its plane shape, and its long side direction is coincident with the X-axis direction, its short side direction is coincident with the Y-axis direction and its width direction (normal line direction of the plate plane of the liquid crystal panel 11) is coincident with the Z-axis direction respectively. The liquid crystal panel 11 has its center side of the screen defined as a display area (active area, pixel area) AA capable of displaying an image thereon, and in contrast, has its peripheral end side defined as a non-display area (non-active area, non-pixel area) NAA surrounding the display area AA. Additionally, in each of FIGS. 1 and 2, a one-dot chain line represents the outline of the display area AA, and an area outside of the one-dot chain line represents the non-display area NAA.

As shown in FIG. 1, the liquid crystal panel 11 is formed by bonding a pair of substantially transparent substrates 11A and 11B (having light transmittance) made of glass to each other with a predetermined interval therebetween. Between the two substrates 11A and 11B, a liquid crystal layer (light modulation material) containing liquid crystal molecules serving as a substance whose alignment is changed in response to application of an electric field and a seal part (not shown together with the liquid crystal layer) made of epoxy resin or the like for maintaining the gap between the two substrates 11A and 11B and for surrounding the liquid crystal layer so as to seal the liquid crystal layer, are interposed therebetween. Of the two substrates 11A and 11B, one on the surface side (front surface side) is prepared as a CF substrate (opposing substrate) 11A and the other on the rear side (back surface side) is prepared as an array substrate (active matrix substrate) 11B. Both of the substrates 11A and 11B have rectangular shapes. Additionally, onto the outer surface side of each of the substrates 11A and 11B, a polarizing plate (not shown) is bonded.

As shown in FIG. 1, the CF substrate 11A has its short side dimension made smaller than that of the array substrate 11B, and bonded to the array substrate 11B, with one of its short side edge parts (upper side shown in FIG. 1) in the Y-axis direction being aligned thereto. Therefore, the other of its short side edge part (lower side shown in FIG. 1) in the Y-axis direction of the array substrate 11B is formed into a CF substrate non-overlapped part 11B1 with which the CF substrate 11A is not overlapped. The CF substrate non-overlapped part 11B1 has its plate surface on the surface side exposed outside without being overlapped with the CF substrate 11A, and parts, such as a driver 12, a flexible substrate (not shown) and the like, to be described later are assembled thereon. On the assembling area of the driver 12, the flexible substrate and the like of the CF substrate non-overlapped part 11B1, various kinds of terminals are formed. Additionally, with respect to the assembling area of the driver 12 and the terminals to be formed thereon, explanation thereof will be given later in detail. The driver 12 has a laterally long rectangular shape, and is COG (Chip On Glass)-assembled on the assembling area of the driver 12 in the CF substrate non-overlapped part 11B1. The driver 12 is made of an LSI chip having a driving circuit therein, and processes various signals from an external signal supply source (control substrate) transmitted by the flexible substrate. Of the CF substrate non-overlapped part 11B1, onto an area on an opposite side to the display area AA side relative to the assembling area of the driver 12, a flexible substrate is assembled. The driver 12 and the flexible substrate are connected to the CF substrate non-overlapped part 11B1 through an anistropic conductive film (ACF: Anistropic Conductive Film), not shown, electrically as well as mechanically.

Next, explanation will be given on the configuration of the display area AA in the liquid crystal panel 11. As shown in FIG. 2, on the display area AA of the array substrate 11B, at least a TFT (thin-film transistor, switching element) 13 and a pixel electrode 14 are formed. The TFT 13 and the pixel electrode 14 constitute a pixel PX serving as a display unit in the liquid crystal panel 11, and a large number of the pixels are disposed along the X-axis direction and Y-axis direction with an interval spaced therebetween in a matrix form (matrix state). On the peripheral portion of these TFT's 13 and the pixel electrodes 14, gate lines (scanning lines, pixel wirings) 15 and source lines (signal lines, pixel wirings) 16, which orthogonally cross (intersect with) each other, are disposed. A large number of the gate lines 15, which extend along the X-axis direction, are disposed in parallel with one another along the Y-axis direction with a predetermined array pitch, while a large number of the source lines 16, which extend along the Y-axis direction, are disposed in parallel with one another along the X-axis direction with a predetermined array pitch. The gate lines 15, which are disposed on the lower layer side relative to a second metal film M2 to be described later, are formed by patterning a first metal film (first conductive film) M1 made of a metal material having a relatively high sheet resistance with a higher melting point, such as Ta (tantalum), W (tungsten) or the like. In contrast, the source lines 16, which are disposed on the upper layer side relative to the first metal film M1 with an insulating film IN interposed therebetween, are formed by patterning a second metal film (second conductive film) M2 made of a metal material having a relatively low sheet resistance with a lower melting point, such as Al (aluminum), Cr (chromium) or the like. Additionally, these respective metal films M1 and M2, as well as the insulating film IN, are illustrated in FIG. 5 or the like. The TFT 13 is provided with a gate electrode connected to the gate lines 15, a source electrode connected to the source line 16, a drain electrode connected to the pixel electrode 14 and a channel part made of a semiconductor material and connected to the source electrode and the drain electrode. As the semiconductor material for the channel part, amorphous silicon, oxide semiconductor, a low temperature polycrystal silicon or the like may be used. Moreover, the TFT 13 is driven based upon a scanning signal supplied to the gate electrode connected to the gate lines 15. Then, an electric potential relating to an image signal (data signal) supplied to the source electrode connected to the source line 16 is further supplied to the drain electrode through the channel part so that the pixel electrode 14 is charged to an electric potential relating to the image signal. The pixel electrode 14 is made of a transparent electrode material (for example, ITO or the like). The pixel electrode 14 is disposed in an area surrounded by the gate lines 15 and the source lines 16. On either the CF substrate 11A or the array substrate 11B, a common electrode (not shown) made of the same transparent electrode material as that of pixel electrode 14 and disposed so as to be overlapped with the pixel electrode 14 is formed, and based upon a potential difference caused between the common electrode and each pixel electrode 14, a predetermined electric field is applied to the liquid crystal layer so that the respective pixels PX are allowed to carry out a predetermined gradation display. Additionally, although its illustration is omitted, on the inner surface side of the display area AA of the CF substrate 11A, color filters of three colors exerting red (R), green (G) and blue (B) colors, a light shielding part (black matrix) for partitioning color filters with three colors and the adjacent color filters and the like are disposed so as to be overlapped with the respective electrodes 14.

Next, explanation will be given on the assembling area (terminal area) of the driver 12 on the array substrate 11B and terminals to be installed therein. As shown in FIG. 2, in the assembling area of the driver 12 on the array substrate 11B, a panel side output terminal part Te for outputting a signal to the driver 12 and a panel side input terminal part (signal input part) 18 to which a signal from the driver 12 is inputted are installed. Additionally, in FIG. 2, the driver 12 and its assembling area (terminal area) are illustrated by a two-dot chain line. The panel side output terminal part Te and the panel side input terminal part 18 are disposed in the assembling area of the driver 12 with a predetermined interval therebetween in the Y-axis direction. Of these, the panel side output terminal part Te is disposed on the flexible substrate side (opposite side to the display area AA side) in the Y-axis direction within the assembling area of the driver 12; in contrast, the panel side input terminal 18 is disposed on the display area AA side (opposite side to the flexible substrate side) in the Y-axis direction. A large number of the panel side output terminal parts Te and a large number of the panel side input terminal parts 18 are linearly disposed in parallel with each other with a predetermined interval therebetween along the X-axis direction, that is, in the long side direction (alignment direction of the source lines 16). In contrast, in the driver 12, a driver side input terminal part electrically connected to the panel side output terminal part Te and a driver side output terminal part (not illustrated together with the driver side input terminal part) electrically connected to the panel side input terminal part 18 are installed. Additionally, in the assembling area of the flexible substrate, an outside connection terminal part (not illustrated together with the connection wiring) that is connected to the panel side output terminal part Te by a connection wiring and receives the supply of an input signal from the flexible substrate side is formed.

In the non-display area NAA of the array substrate 11B, between the display area AA and the assembling area (terminal area) of the driver 12, as shown in FIG. 2, a source circuit part (column circuit part) 17 to be connected to the source line 16 in the display area AA and a wiring area WA in which respective wirings 20, 21 for use in connecting the source circuit part 17 and the panel side input terminal part 18 are disposed, are disposed. The source circuit part 17 is monolithically formed on the array substrate 11B by using the same semiconductor material as that of the TFT 13 as a base material. The source circuit part 17 is disposed at a position adjacent to the display area AA in the Y-axis direction, and connected to the end part of each of the source lines 16. The source circuit part 17 is provided with a switching circuit (RGB switching circuit) for use in distributing an image signal contained in the output signal supplied from the driver 12 side to the respective source lines 16. More specifically, a large number of the source lines 16 are disposed in parallel with one another along the X-axis direction in the display area AA, and respectively connected to the respective TFT's 13 forming the pixels PX having respective colors of red, green and blue colors; in contrast, the source circuit part 17 supplies the image signal supplied from the driver 12 side by the switching circuit in a manner so as to be distributed to the respective source lines 16 representing the respective colors of red, green and blue colors. Therefore, the source circuit part 17 is designed so as to make the formation range in the X-axis direction equal to the display area AA so as to be connected to all the source lines 16, and becomes wider than the assembling area of the driver 12.

As shown in FIG. 2, the wiring area WA is disposed between the assembling areas (panel side input terminal parts 18) of the source circuit part 17 and the driver 12 in the Y-axis direction within the non-display area NAA of the array substrate 11B. In this case, when the assembling areas of the source circuit part 17 and the driver 12 are compared with each other, the formation range in the X-axis direction of the former is wider than that of the latter. Therefore, the wiring area WA has its formation range in the X-axis direction made wider toward the source circuit part 17 side, and has its formation range in the X-axis direction made narrower toward the assembling area side of the driver 12. Moreover, the respective wirings 20 and 21 to be formed in the wiring area WA are disposed in a manner so as to be concentrated into a substantially fan shape from the source circuit part 17 side toward the assembling area side of the driver 12. In the wiring area WA, the first wirings 20 a plurality of which are disposed on each of the two end sides in the X-axis direction (aligning direction of the source lines 16) and the second wirings 21 a plurality of which are disposed in the center side in the X-axis direction and whose wiring length is shorter than that of the first wirings 20 are installed. The installation numbers of these first wirings 20 and second wirings 21 are set to about ⅓ of the installation numbers of the source lines 16. Each of the first wirings 20 and each of the second wirings 21 are respectively provided with a first diagonally extending part 22 and a second diagonally extending part 23 that extend in diagonal directions relative to the X-axis direction and the Y-axis direction and are placed in the mid way from the source circuit part 17 to reach the assembling area of the driver 12, and the first diagonally extending part 22 of the first wirings 20 to be disposed on the end side has a longer wiring length than that of the second diagonally extending part 23 of the second wiring 21 to be disposed in the center side. This is because each of the first wirings 20 has a distance in the X-axis direction between the connection position to the source circuit part 17 and the connection position to the panel side input terminal part 18 that is made longer than the same distance relating to the second wiring 21. Moreover, the wiring lengths of the first wiring 20 and the second wiring 21 tend to become longer as the layout position in the X-axis direction becomes closer to the end side, while in contrast, they tend to become shorter as the layout position relating to the connector becomes closer to the center side. This is because in the first wirings 20 and the second wirings 21, a distance in the X-axis direction between the connection position on the source circuit part 17 side and the connection position on the panel side input terminal part 18 side becomes larger toward the end side in the X-axis direction and in contrast, it becomes smaller toward the center side in the X-axis direction.

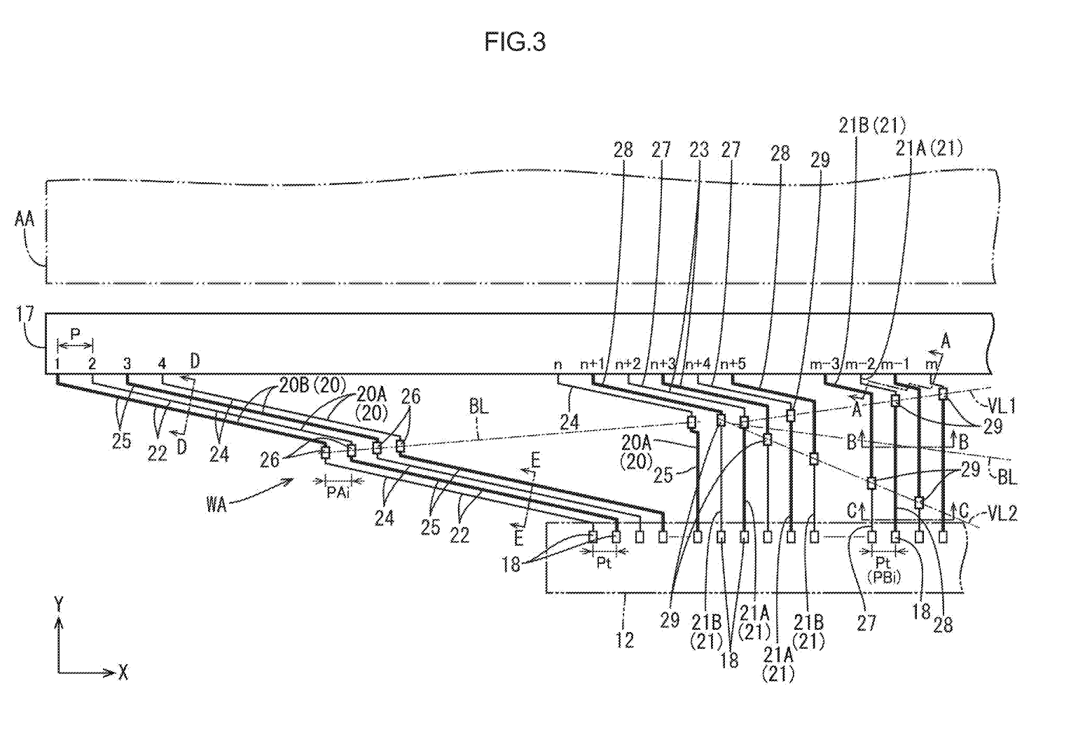

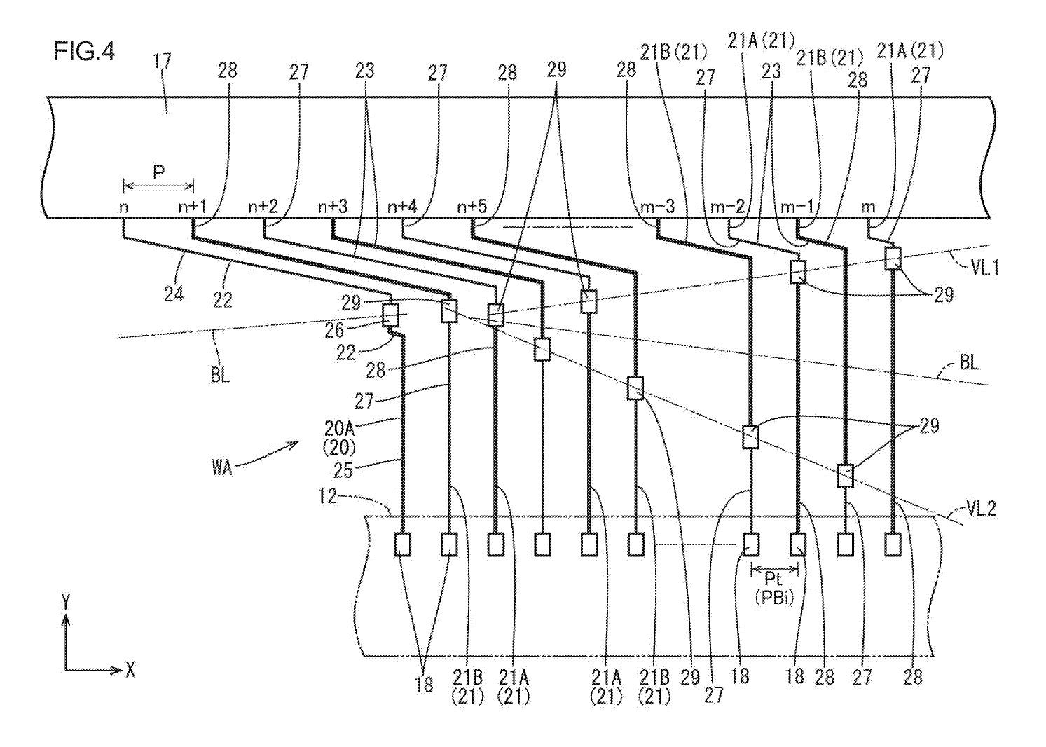

Moreover, as shown in FIG. 3, the first wiring 20 is constituted by a first low resistance wiring part 24, a first high resistance wiring part 25 having a higher resistance than that of the first low resistance wiring part 24 and a first connection part 26 that connects the first low resistance wiring part 24 and the first high resistance wiring part 25 with each other. Additionally, in FIGS. 3 and 4, the first high resistance wiring part 25 is illustrated by a thick line and the first low resistance wiring part 24 is illustrated by a thin line respectively. Moreover, the line width of the first high resistance wiring part 25 is set to be thicker than the line width of the first low resistance wiring part 24. The first low resistance wiring part 24 has its one of end parts (one end side) either indirectly connected to the source line 16 through the source circuit part 17, or directly connected to the panel side input terminal part 18. The first high resistance wiring part 25 has its one of end parts (one end side) either directly connected to the panel side input terminal part 18, or indirectly connected to the source line 16 through the source circuit part 17. The first low resistance wiring part 24 and the first high resistance wiring part 25 have their other end parts (the other end side) connected to each other by the first connection part 26. The second wiring 21 is constituted by a second low resistance wiring part 27, a second high resistance wiring part 28 having a higher resistance than that of the second low resistance wiring part 27 and a second connection part 29 that connects the second low resistance wiring part 27 and the second high resistance wiring part 28 with each other. Additionally, in FIGS. 3 and 4, the second high resistance wiring part 28 is illustrated by a thick line and the second low resistance wiring part 27 is illustrated by a thin line respectively. Furthermore, the line width of the second high resistance wiring part 28 is made thicker than the line width of the second low resistance wiring part 27. The second low resistance wiring part 27 has its one of end parts (one end side) either indirectly connected to the source line 16 through the source circuit part 17, or directly connected to the panel side input terminal terminal part 18. The second high resistance wiring part 28 has its one of end parts (one end side) either directly connected to the panel side input terminal part 18, or indirectly connected to the source line 16 through the source circuit part 17. The second low resistance wiring part 27 and the second high resistance wiring part 28 have their other end parts (the other end side) connected to each other by a second connection part 29. Additionally, in FIG. 3, a half of the left side of each of the source circuit part 17 and the panel side input terminal part 18 is typically illustrated, and of the first wiring 20 and the second wiring 21 to be connected thereto, the first wiring 20 positioned at the left end (the most end side) is defined as “the first one”, and the second wiring 21 positioned at the right end (the most center side) is defined as “the m-th one” so that the corresponding number is added onto the source circuit part 17. In FIG. 3, the installation number of the first wirings 20 is “n”, and the installation number of the second wirings 21 is “m−n”. Therefore, the total installation number of the first wirings 20 on the array substrate 11B is represented by “2n”, and the total installation number of the second wirings 21 thereon is represented by “2 (m−n)”.

As shown in FIG. 3, the first wiring 20 has a configuration in which the first connection part 26 is placed such a position as to make the wiring lengths of the first low resistance wiring part 24 and the first high resistance wiring part 25 equal to each other. In other words, the first low resistance wiring part 24 and the first high resistance wiring part 25 have ratios of the wiring lengths occupied in the first wiring 20 made to be substantially equal to each other. In contrast, the second wiring 21 has a configuration in which the second connection part 29 is disposed at a position that makes the wiring lengths of the second low resistance wiring part 27 and the second high resistance wiring part 28 different from each other, and its position is set so as to make the wiring length of the second high resistance wiring part 28 longer than the wiring length of the second low resistance wiring part. 27. In other words, the second high resistance wiring part 28 has its ratio of the wiring length occupied in the second wiring 21 made higher than the corresponding ratio relating to the second low resistance wiring part 27 so that the degree of freedom in the configuration is enhanced in comparison with the prior art configuration. With this arrangement, even when the entire wiring length of the second wiring 21 is shorter than the first wiring 20, it becomes possible to prevent the wiring resistance relating to the second wiring 21 from becoming too low. Therefore, even in the case when an ESD (Electro-Static Discharge) is inputted to the second wiring 21, it becomes possible to make an electrostatic breakdown hardly occur in the TFT 13 or the like constituting the pixel PX connected to the second wiring 21 through the source circuit part 17 and the source line 16. When an electrostatic breakdown is made hardly occur in the TFT 13 or the like constituting the pixel PX connected to the second wiring 21 through the source circuit part 17 and the source line 16, it becomes unnecessary, for example, to connect an ESD protection circuit to the second wiring 21, and even in the case when, for example, the ESD protection circuit is connected, it is only necessary to use a simple, small-size ESD protection circuit. Thus, since the layout space for the second wiring 21 can be reduced, the wiring area WA can be miniaturized and consequently, the array substrate 11B and the liquid crystal panel 11 are allowed to have a narrower frame size.

More specifically, as shown in FIG. 3, each of the plural second wirings 21 that are aligned in parallel with one another along the X-axis direction (aligning direction of the source lines 16) includes one of second wirings 21A in which the second low resistance wiring part 27 connected to the source line 16 through the source circuit part 17 and the second high resistance wiring part 28 connected to the panel side input terminal part 18 are connected to each other by the second connection part 29 and the other second wiring 21B in which the second high resistance wiring part 28 connected to the source line 16 through the source circuit part 17 and the second low resistance wiring part 27 connected to the panel side input terminal part 18 are connected to each other by the second connection part 29. One of the second wirings 21A and the other second wiring 21B are disposed so as to be alternately repeated along the X-axis direction. More specifically, one of the second wirings 21A is disposed at (n+2)-th place, (n+4)-th place, (n+6)-th place, . . . (m−2)-th place and m-th place, while the other second wiring 21B is disposed at (n+1)-th place, (n+3)-th place, (n+5)-th place, . . . (m−3)-th place, (m−1)-th place.

Moreover, as shown in FIG. 3, the plural second connection parts 29 relating to the plural second wirings 21 are disposed on a first hypothetical line VL1 that is biasly located on the source circuit part 17 side (source line 16 side) in the Y-axis direction relative to a reference hypothetical line BL that passes through a position that makes the extending face distance from the source circuit part 17 connected to the source line 16 in the plural second wirings 21 and the extending face distance from the panel side input terminal part 18 equal to each other, as well as on a second hypothetical line VL2 that is biasly located on the panel side input terminal part 18 side in the Y-axis direction relative to the reference hypothetical line BL. With this arrangement, the plural second connection parts 29 disposed on the first hypothetical line VL1 and the second hypothetical line VL2 are alternately dispersed on the source line 16 side as well as on the signal input side relative to the above-mentioned reference hypothetical line BL. Thus, for example, supposedly in comparison with a case in which the plural second connection parts are collectively disposed on the one of the first hypothetical line VL1 or the second hypothetical line VL2 that is biasly located on the source line 16 side or the panel side input terminal part 18 side relative to the above-mentioned reference hypothetical line BL, since it becomes possible to lower the distribution density relating to the plural second connection parts 29, a narrower frame size can be more desirably obtained.

More specifically, as shown in FIG. 4, the plural second connection parts 29 installed in the plural second wirings 21 are disposed on the first hypothetical line VL1 as well as on the second hypothetical line VL2 so as to make the wiring resistance of the second wirings 21 higher as the wiring length of the second wirings 21 becomes shorter. More specifically, the second connection parts 29 installed in the second wirings 21 which are disposed on the end side relative to the X-axis direction and whose wiring length is relatively long are disposed relatively near the reference hypothetical line BL so that with this arrangement, the ratio of the wiring length of the second high resistance wiring part 28 occupied in the second wiring 21 becomes lower than that of the second wiring 21 disposed on the center side. In contrast, the second connection parts 29 installed in the second wirings 21 which are disposed on the center side in the X-axis direction and whose wiring length is relatively short are disposed at a position relatively far from the reference hypothetical line BL so that with this arrangement, the ratio of the wiring length of the second high resistance wiring part 28 occupied in the second wiring 21 becomes higher than that of the second wiring 21 disposed on the end side. As described above, when the second wirings 21 which are disposed on the end side in the X-axis direction and whose wiring length is relatively long and the second wirings 21 which are disposed in the center side in the X-axis direction and whose wiring length is relatively short are compared with each other, the wiring resistance of the latter becomes higher than that of the former. With this arrangement, since the plural second connection parts 29 are disposed on the first hypothetical line VL1 as well as on the second hypothetical line VL2 so as to allow the second wirings 21 having a shorter wiring length, which might cause the occurrence of an electrostatic breakdown due to an ESD, to have a higher wiring resistance so that the occurrence of a electrostatic breakdown can be more desirably suppressed. Moreover, the plural second connection parts 29 are disposed so as to make the first hypothetical line VL1 and the second hypothetical line VL2 form straight lines respectively. With this arrangement, the plural second wirings 21 are allowed to have the ratios of the respective wiring lengths of the second low resistance wiring parts 27 and the second high resistance wiring parts 28 occupied in the second wirings 21 that are made to vary in response to the layout in the X-axis direction. That is, as the plural second wirings 21 are disposed on the center side to have a shorter wiring length, the ratio of the wiring length of the second high resistance wiring part 28 occupied in the second wirings 21 becomes gradually higher continuously. Thus, even in the case when an ESD is inputted to the second wiring 21 whose wiring length is shorter among the plural second wirings 21, it becomes possible to make an electrostatic breakdown hardly occur in the pixel PX or the like connected to the second wiring 21 through the source line 16.

Moreover, in the second wirings 21, as shown in FIG. 4, the second low resistance wiring part 27 or the second high resistance wiring part 28 connected to the source line 16 through the source circuit part 17 is provided with a second diagonally extending part 23 and in contrast, the second high resistance wiring part 28 or the second low resistance wiring part 27 connected to the panel side input terminal part 18 is not provided with the second diagonally extending part 23. The second diagonally extending part 23 constitutes a center portion excluding the two end portions in the second low resistance wiring part 27 or the second high resistance wiring part 28 connected to the source line 16 through the source circuit part 17. With this arrangement, the second low resistance wiring part 27 or the second high resistance wiring part 28 connected to the source line 16 through the source circuit part 17 has its other end part to be connected to the second connection part 29 relative to one of the end parts connected to the source circuit part 17 biasly located on the center side in the X-axis direction. On the other hand, the second high resistance wiring part 28 or the second low resistance wiring part 27 to be connected to the panel side input terminal part 18 has its one of end parts to be connected to the panel side input terminal part 18 relative to the other end part connected to the second connection part 29 linearly routed along the Y-axis direction (direction orthogonal to the aligning direction) so as to be disposed at the same position in the X-axis direction. With this arrangement, an array pitch PBi between the adjacent second connection parts 29 in the X-axis direction is set to be the same array pitch Pt between the adjacent panel side input terminal parts 18 in the X-axis direction.

As shown in FIGS. 5 to 7, the second high resistance wiring part 28 is made of a first metal film (first conductive film) M1, while the second low resistance wiring part 27 is disposed on a layer different from the first metal film M1 with the insulating film IN interposed therebetween, and is made of a second metal film (second conductive film) M2 having a lower sheet resistance than that of the first metal film M1. That is, the material for the second high resistance wiring part 28 is the same as that of the gate line 15, while the material for the second low resistance wiring part 27 is the same as that of the source line 16. With this arrangement, in comparison with a case in which the second low resistance wiring part and the second high resistance wiring part are supposedly disposed on the same layer, the degree of freedom relating to the plane layout of the second low resistance wiring part 27 and the second high resistance wiring part 28 can be enhanced. Thus, a narrower frame size can be desirably obtained. Moreover, since the sheet resistances between the first metal film M1 and the second metal film M2 are made different from each other, the degree of freedom relating to the width dimension and thickness of the second low resistance wiring part 27 and the second high resistance wiring part 28 can be enhanced. More specifically, in the present embodiment, as shown in FIG. 4, one of the second wirings 21A and the other second wiring 21B are disposed so as to be alternately repeated, with the second low resistance wiring part 27 having the second diagonally extending part 23 and the second high resistance wiring part 28 having the second diagonally extending part 23 being adjacent to each other in the X-axis direction so as to be non-overlapped with each other. With this arrangement, in comparison with a case in which the second low resistance wiring part having the second diagonally extending part 23 and the second high resistance wiring part having the second diagonally extending part 23 are supposedly disposed so as to be overlapped with each other, it becomes possible to reduce a parasitic capacitance that tends to be generated between the second low resistance wiring part 27 having the second diagonally extending part 23 and the second high resistance wiring part 28 having the second diagonally extending part 23.

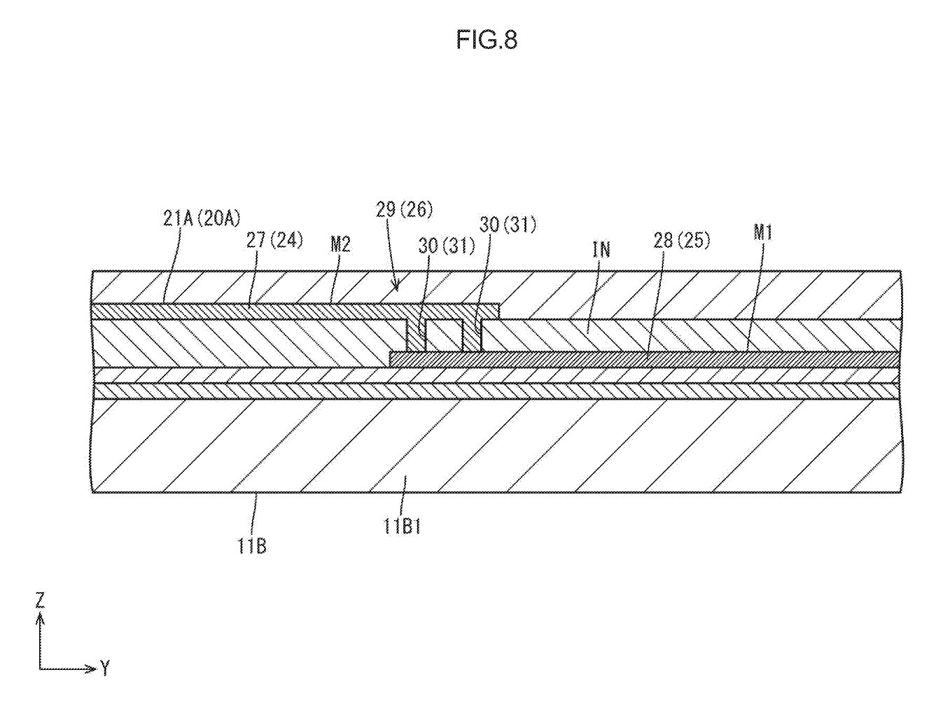

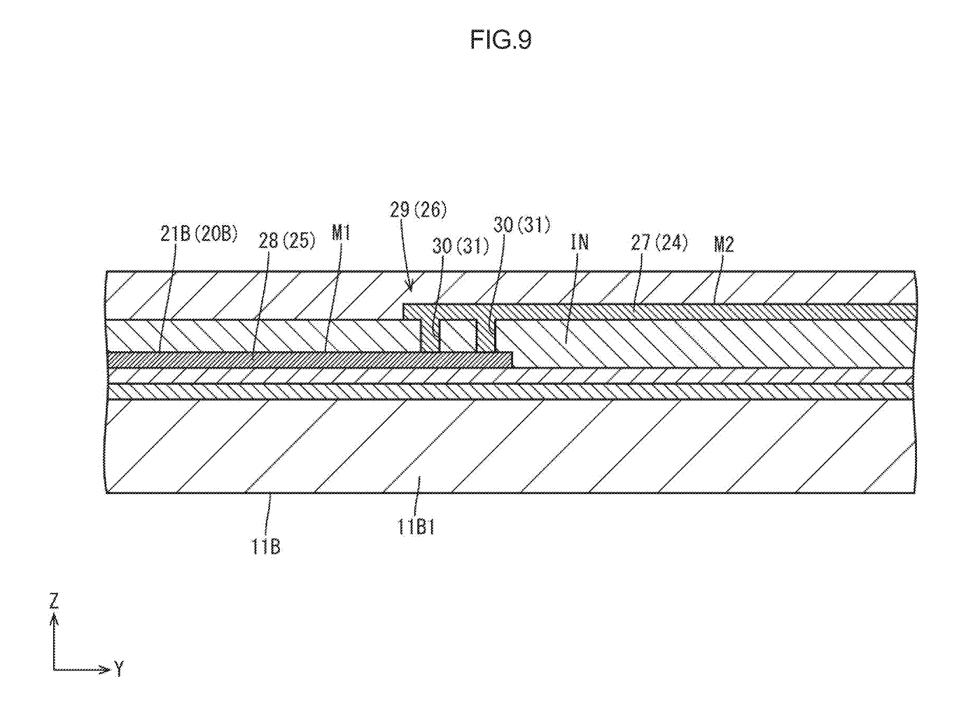

As shown in FIGS. 8 and 9, the second wirings 21 are disposed so as to make the other end part of the second low resistance wiring part 27 and the other end part of the second high resistance wiring part 28 overlapped with each other. Moreover, the second connection part 29 is constituted by an overlapped portion between the second low resistance wiring part 27 and the second high resistance wiring part 28, and a second contact hole 30 that is formed so as to be opened on the insulating film IN and connects the mutual overlapped portions between the second low resistance wiring part 27 and the second high resistance wiring part 28. The second contact holes 30 are disposed in parallel with one another with an interval formed between the two along the Y-axis direction.

Successively, explanation will be given on the first wirings 20 in detail. As shown in FIG. 3, the plural first wirings 20 aligned along the X-axis direction are provided with one of the first wirings 20A include one of the first wirings 20A in which the first low resistance wiring part 24 to be connected to the source line 16 through the source circuit part 17 and the first high resistance wiring part 25 to be connected to the panel side input terminal part 18 are connected to each other by the first connection part 26 and the other first wiring 20B in which the first high resistance wiring part 25 to be connected to the source line 16 through the source circuit part 17 and the first low resistance wiring part 24 to be connected to the panel side input terminal part 18 are connected to each other by the first connection part 26. One of the first wirings 20A and the other first wiring 20B are disposed so as to be alternately repeated along the X-axis direction. More specifically, one of the first wirings 20A is disposed at the second place, the fourth place, the sixth place, . . . (n−2)-th place, and n-th place, while the other first wiring 20B is disposed at the first place, the third place, the fifth place, . . . (n−3)-th place, and (n−1)-th place.

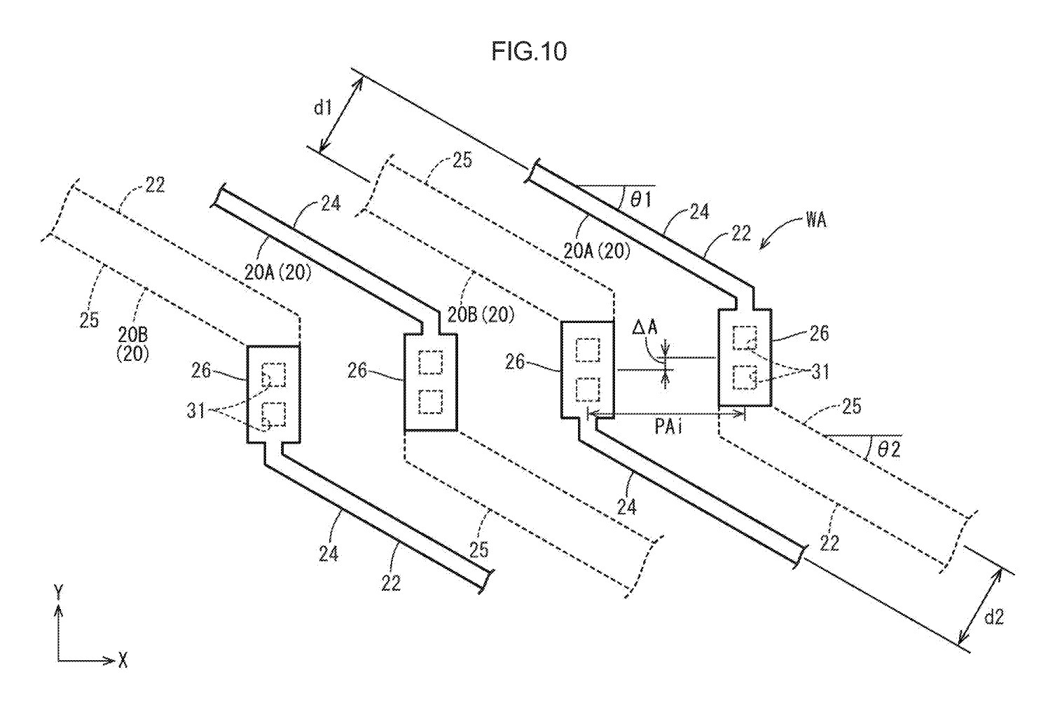

As shown in FIG. 3, the first low resistance wiring part 24 or the first high resistance wiring part 25 to be connected to the source line 16 through the source circuit part 17 and the first high resistance wiring part 25 or the first low resistance wiring part 24 to be connected to the panel side input terminal part 18 are respectively provided with first diagonally extending parts 22. The first diagonally extending part 22 constitutes a center portion excluding the two end portions in the first low resistance wiring part 24 or the first high resistance wiring part 25. With this arrangement, the first low resistance wiring part 24 or the first high resistance wiring part 25 to be connected to the source line 16 through the source circuit part 17 has its other end part to be connected to the first connection part 26 relative to one of the end parts connected to the source line 16 through the source circuit part 17 biasly located on the center side in the X-axis direction. On the other hand, the first high resistance wiring part 25 or the first low resistance wiring part 24 to be connected to the panel side input terminal part 18 has its one of end parts to be connected to the panel side input terminal part 18 relative to the other end part connected to the first connection part 26 biasly located on the center side in the X-axis direction. Moreover, the plural first connection parts 26 have their array pitch PAi made narrower than a lead-out pitch P and as those parts are disposed further center side in the X-axis direction, those are disposed so as to be further shifted toward the source line 16 side in the Y-axis direction. In other words, the plural first connection parts 26 are disposed on a reference hypothetical line BL that is tilted so as to come closer (depart from the panel side input terminal part 18) to the source line 16 in the Y-axis direction toward the center side from the end side in the X-axis direction. With this arrangement, in the plural first wirings 20, since the first low resistance wiring part 24 or the first high resistance wiring part 25 to be connected to the source line 16 and the first high resistance wiring part 25 or the first low resistance wiring part 24 to be connected to the panel side input terminal part 18 are respectively routed along a diagonal direction, and since the array pitch PAi of the plural first connection parts 26 is made narrower than the lead-out pitch P, the layout space for the plural first wirings 20 can be made smaller. Thus, a narrower frame size can be desirably obtained. In addition to this, as shown in FIG. 10, since the plural first connection parts 26 are disposed so as to be further shifted toward the source line 16 side, as those are further disposed on the center side in the X-axis direction, it becomes more desirable in adjusting an array pitch d1 or d2 between the adjacent first wirings 20, or in adjusting an angle θ1 or θ2 made by the first diagonally extending part 22 of the first low resistance wiring part 24 or the first high resistance wiring part 25 relative to the X-axis direction.

More specifically, as shown in FIG. 3 and FIG. 10, first, of the first wirings 20, a lead-out pitch is defined as “P”, an array pitch of the first low resistance wiring part 24 or the first high resistance wiring part 25 to be connected to the source line 16 through the source circuit part 17 is defined as “d1”, and an angle made by the first diagonally extending part 22 possessed by the first low resistance wiring part 24 or the first high resistance wiring part 25 to be connected to the source line 16 through the source circuit part 17 relative to the X-axis direction is defined as “θ 1”. At this time, formula (1) of “Sin 1=d1/P” is satisfied. On the other hand, as shown in FIG. 10, of the first wirings 20, an array pitch of the first connection parts 26 is defined as “PAi”, an array pitch of the first high resistance wiring pats 25 or the first low resistance wiring parts 24 to be connected to the panel side input terminal part 18 is defined as “d2”, an angle made by the first diagonally extending part 22 possessed by the first high resistance wiring part 25 or the first low resistance wiring part 24 to be connected to the panel side input terminal part 18 relative to the X-axis direction is defined as “02”, and a distance (shift amount) in the Y-axis direction between the adjacent first connection parts 26 in the X-axis direction is defined as “ΔA”. At this time, formula (2) of “Sin θ2=d2/(PAi+ΔA)” is satisfied. In accordance with these formulas (1) and (2), if AA is supposedly set to 0, in the case when d1 and d2 are set to equal to each other, θ2>θ1 is inevitably held and in this case, the layout space of the first high resistance wiring part 25 or the first low resistance wiring part 24 to be connected to the panel side input terminal part 18 becomes bulky. At this point, by appropriately setting the value of ΔA, θ1 and θ2 can be set equal to each other even in the case when d1 and d2 are made equal to each other. With this arrangement, the first low resistance wiring part 24 or the first high resistance wiring part 25 to be connected to the source lines 16 in the plural first wirings 20 and the first high resistance wiring part 25 or the first low resistance wiring part 24 to be connected to the panel side input terminal terminal part 18 are made in parallel with each other so that the plural first wirings 20 can be effectively routed out. Thus, a narrower frame size can be further desirably achieved. Moreover, since the array pitches d1 and d2 between the adjacent first wirings 20 located from the source line 16 to reach the panel side input terminal part 18 can be uniformed, the plural first wirings 20 can be effectively routed out. Thus, a narrower frame size can be further desirably achieved.

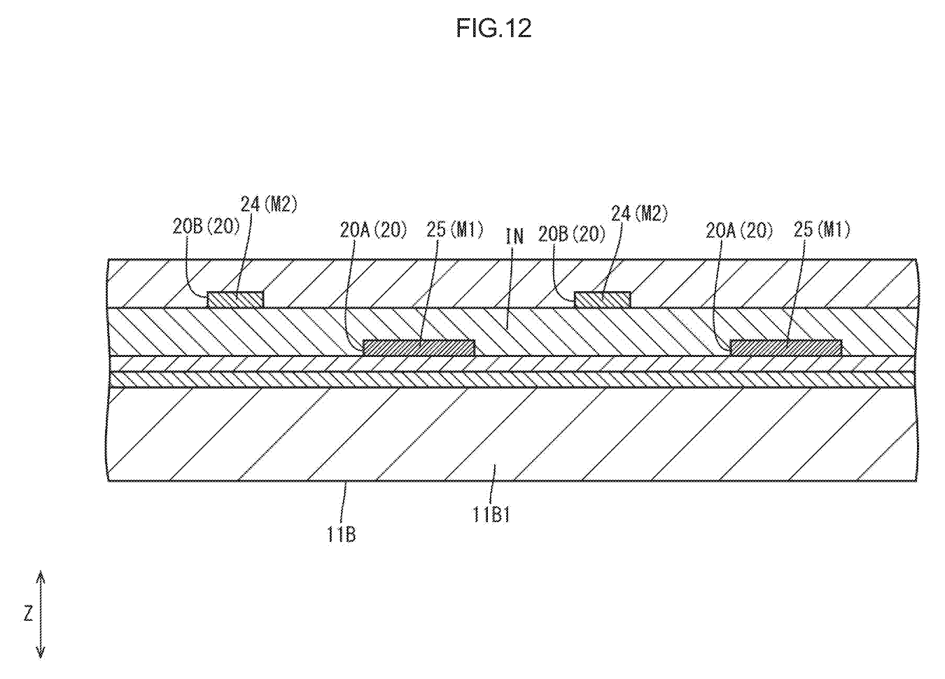

As shown in FIG. 11 and FIG. 12, the first high resistance wiring part 25 is made of the first metal film M1; in contrast, the first low resistance wiring part 24 is disposed on a layer different from the first metal film M1, with an insulating film IN interposed therebetween, and is made of a second metal film M2 having a lower sheet resistance than that of the first metal film M1. That is, the material for the first high resistance wiring part 25 is the same as that of the gate line 15 and the second high resistance wiring part 28; in contrast, the material for the first low resistance wiring part 24 is the same as that of the source line 16 and the second low resistance wiring part 27. With this arrangement, in comparison with a case where the first low resistance wiring part and the first high resistance wiring part are supposedly disposed on the same layer, the degree of freedom relating to the plane layout of the first low resistance wiring part 24 and the first high resistance wiring part 25 becomes higher. Thus, a narrower frame size can be more desirably achieved. Moreover, since the sheet resistances of the first metal film M1 and the second metal film M2 are made different from each other, the degree of freedom relating to the width dimension and thickness of the first low resistance wiring part 24 and the first high resistance wiring part 25 can be enhanced. More specifically, in the present embodiment, as shown in FIG. 10, one of the first wirings 20A and the other first wiring 20B are disposed so as to be alternately repeated; however, the first low resistance wiring part 24 having the first diagonally extending part 22 and the first high resistance wiring part 25 having the first diagonally extending part 22 are made adjacent to each other in the X-axis direction so as to be also mutually non-overlapped with each other. With this arrangement, in comparison with a case where the first low resistance wiring part having the first diagonally extending part 22 and the first high resistance wiring part having the first diagonally extending part 22 are supposedly disposed so as to be overlapped with each other, it becomes possible to reduce a parasitic capacitance that tends to be generated between the first low resistance wiring part 24 having the first diagonally extending part 22 and the first high resistance wiring part 25 having the first diagonally extending part 22.

As shown in FIG. 8 and FIG. 9, the first wirings 20 are disposed so as to make the other end part of the first low resistance wiring part 24 and the other end part of the first high resistance wiring part 25 are mutually overlapped with each other. Moreover, the first connection part 26 is constituted by the overlapped portion between the first low resistance wiring part 24 and the first high resistance wiring part 25 and a first contact hole 31 that is formed to be opened on the insulating film IN so as to connect mutual overlapped portions between the first low resistance wiring part 24 and the first high resistance wiring part 25 with each other. The first contact holes 31 are disposed in parallel with one another with an interval formed between the two along the Y-axis direction. Additionally, in FIG. 8 and FIG. 9, symbols relating to the first wirings 20 are written in parentheses.

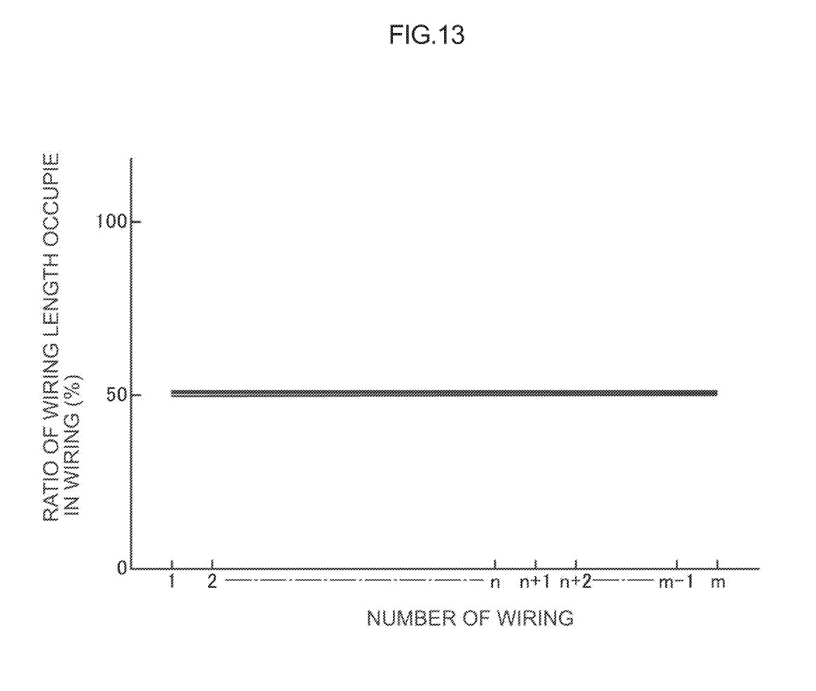

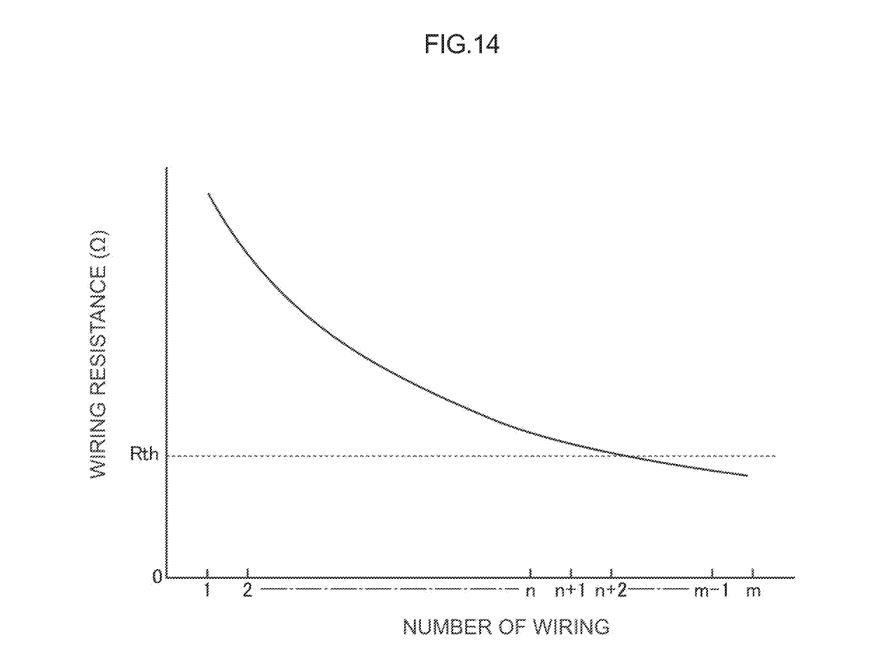

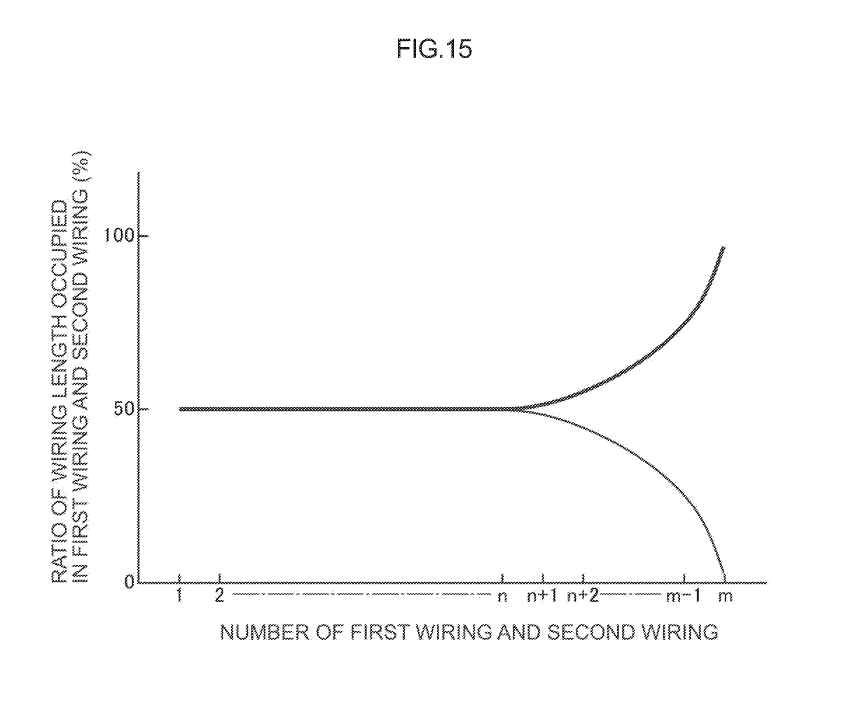

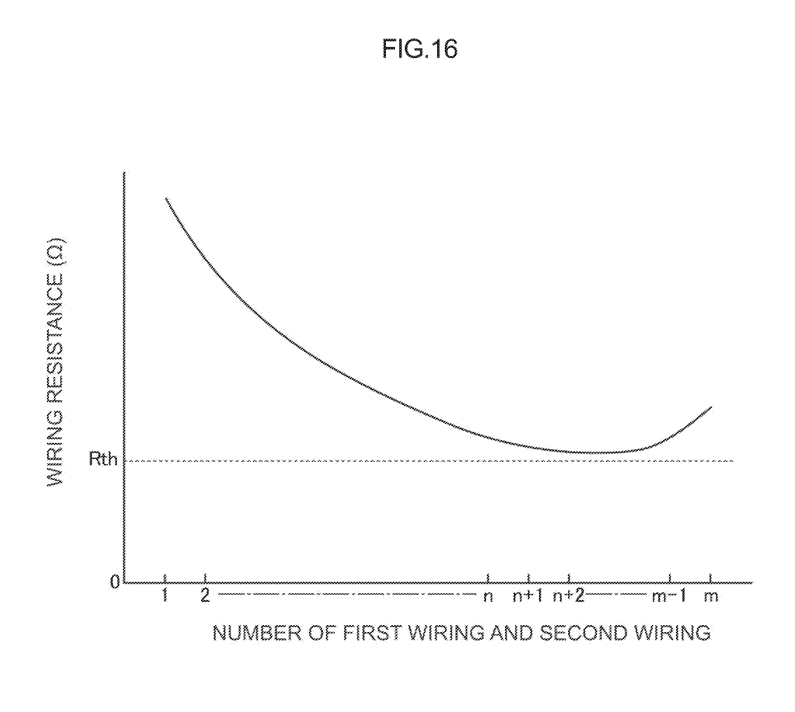

Next, contrasting explanation will be given on the present embodiment and the prior art. In this contrasting explanation, FIGS. 13 to 16 are used, FIG. 13 and FIG. 14 are graphs relating to the prior art, and FIG. 15 and FIG. 16 are graphs relating to the present embodiment. In FIG. 13 and FIG. 15, the lateral axis represents numbers of respective wrings disposed in a wiring area, and the longitudinal axis represents ratios (“%” in unit) of wiring lengths of a low resistance wiring part and a high resistance wiring part occupied in the respective wirings respectively, and the graph of a thin line represents the low resistance wiring part and the graph of a thick line represents the high resistance wiring part respectively. In FIG. 14 and FIG. 16, the lateral axis represents the number of each of wirings disposed in a wiring area, and the longitudinal axis represents a wiring resistance (“0” in unit) of the wiring.

First, in the prior art, as shown in FIG. 13, the ratio of wiring lengths of a low resistance wiring part and a high resistance wiring part occupied in the wirings is set to a constant value of 50%. That is, with respect to the first wiring having the longest wiring length which is positioned closest to the end relative to the X-axis direction and the m-th wiring having the shortest wiring length which is positioned closest to the center in the X-axis direction, the ratios of wiring lengths of the low resistance wiring part and the high resistance wiring part occupied in the wirings are respectively set to the same ratio of 50%. Therefore, in the prior art, as shown in FIG. 14, the wiring resistance of wiring and the wiring length of wiring have correlation with each other, and the wiring resistance of the wiring tends to be reduced constantly from the end side toward the center side in the X-axis direction. In particular, the wiring disposed close to the center in the X-axis direction includes those wirings having wiring resistance lower than the threshold value Rth (more specifically, wirings from (n+2)-th place to m-th place). In the case of the wiring resistance lower than the threshold value Rth, when an ESD is inputted to the wiring, a TFT connected to the wiring might be highly subject to an electrostatic breakdown, with the result that it can be said that the prior art has a problem in ESD resistance function. In contrast, in the present embodiment, as shown in FIG. 15, although the ratios of wiring lengths of the first low resistance wiring part 24 and the first high resistance wiring part 25 occupied in the first wirings 20 are respectively set to a constant ratio of 50%, the ratio of the wiring length of the second high resistance wiring part 28 occupied in the second wiring length 21 becomes higher than the ratio of the wiring length of the second low resistance wiring part 27 occupied therein. In other words, with respect to the first wiring 20 positioned at the first place having the longest wiring length and positioned closest to the end in the X-axis direction and the n-th first wiring 20 having the shortest wiring length and positioned closest to the center in the X-axis direction, the ratios of wiring lengths of the first low resistance wiring part 24 and the first high resistance wiring part 25 occupied in the first wirings 20 are respectively set to the same ratio of 50%. In contrast, in the (n+1)-th second wiring 21 having the longest wiring length which is positioned closest to the end in the X-axis direction, the ratio of the wiring length of the second high resistance wiring part 28 occupied in the second wiring 21 is set to a value exceeding 50%, and in the m-th second wiring 21 having the shortest wiring length which is positioned closest to the center in the X-axis direction, the ratio of the wiring length of the second high resistance wiring part. 28 occupied in the second wiring 21 is set to the highest value (100% or less). Therefore, in the present embodiment, as shown in FIG. 16, although the wiring resistance of the first wiring 20 and the wiring length of the first wiring 20 have correlation with each other, the wiring resistance of the second wiring 21 has inverse correlation with the wiring length of the second wiring 21. That is, although the wiring resistance of the first wiring 20 tends to be constantly reduced from the end side toward the center side in the X-axis direction, the wiring resistance of the second wiring 21 tends to increase from the end side toward the center side in the X-axis direction. Moreover, although the second wiring 21 has a shorter wiring length in comparison with the first wiring 20, its wiring resistance does not fall below the threshold value Rth. Thus, even in the case when an ESD is inputted to the second wiring 21, such situations that an electrostatic breakdown occurs in the TFT 13 connected to the second wiring 21 are hardly generated.

As explained above, the array substrate (active matrix substrate) 11B of the present embodiment is provided with: pixels PX; source lines (pixel wirings) 16 that are connected to the pixels PX; panel side input terminal parts (signal input parts) 18 for use in inputting a signal to the above-mentioned source lines 16; a second wiring (wiring) 21 that is connected to the source lines 16 and the panel side input terminal parts 18; a second wiring (wiring part) 21 connected to the source lines 16 and the panel side input terminal parts 18; a second low resistance wiring part (low resistance wiring part) 27 which constitutes the second wiring 21, one of whose end parts (one end side) is connected to the panel side input terminal parts 18 or the source lines 16; a second high resistance wiring part (high resistance wiring part) 28 which constitutes the second wiring 21, has its one end side (one end side) connected to the panel side input terminal parts 18 or the source wrings 16, also has a resistance higher than that of the second low resistance wiring part 27, and is designed so that the ratio of the wiring length occupied in the second wiring 21 is higher than the ratio of the second low resistance wiring part 27; and second connection parts (connection parts) 29 that connect the other end parts (other end side) of the second low resistance wiring part 27 and the second high resistance wiring part 28 with each other.

By using this method, a signal from the panel side input terminal parts 18 is transmitted to the source line 16 through the wiring 21, and then supplied to the pixels PX. The second wirings 21 have enhanced degree of freedom in comparison with the prior art so that the ratio of the wiring length of the second high resistance wiring part 28 occupied in the second wirings 21 is made higher than the corresponding ratio of the second low resistance wiring part 27; therefore, even when the entire wiring length in the plural second wirings 21 becomes shorter, it is possible to prevent the wiring resistance relating to the second wirings 21 from becoming too low. Therefore, even in the case when an ESD is inputted to the second wirings 21, an electrostatic breakdown hardly occurs in the pixel PX or the like connected to the second wirings 21 through the source lines 16. In the case when the electrostatic breakdown comes to hardly occur in the pixel PX or the like connected to the second wirings 21 though the source lines 16, for example, it becomes not necessary to connect an ESD protection circuit to the second wirings 21, and even in the case of, supposedly, connecting the ESD protection circuit, it is only necessary to use a simple small-size ESD protection circuit. Thus, since the layout space for the second wirings 21 can be reduced, it becomes possible to desirably achieve a narrower frame.

Moreover, the plural second wirings 21 are disposed in parallel with one another, and include one of second wirings (one of wirings) 21A in which the second low resistance wiring part 27 connected to the source line 16 and the second high resistance wiring part 28 connected to the panel side input terminal part 18 are connected to each other by the second connection part 29 and the other second wiring (the other wiring) 21B in which the second high resistance wiring part 28 connected to the source line 16 and the second low resistance wiring part 27 connected to the panel side input terminal part 18 are connected to each other by the second connection parts 29, and the plural second connection parts 29 are disposed on a first hypothetical line VL1 that is biasly located on the source line 16 side relative to a reference hypothetical line BL that passes through a position which makes an extending face distance from the source line 16 in the plural second wirings 21 and an extending face distance from the panel side input terminal part 18 side equal to each other, as well as on a second hypothetical line VL2 that is biasly located on the panel side input terminal part 18 side relative to the reference hypothetical line BL. With this arrangement, the plural second connection parts 29 disposed on the first hypothetical line VL1 and on the second hypothetical line VL2 are alternately dispersed on the source line 16 side as well as on the signal input side relative to the above-mentioned reference hypothetical line BL. Thus, in comparison with a case in which supposedly the plural second connection parts 29 are collectively disposed on a single hypothetical line biasly located on the source line 16 side or the panel side input terminal part 18 side relative to the above-mentioned reference hypothetical line BL, it becomes possible to lower the distribution density relating to the plural second connection parts 29; therefore, a narrower frame size can be desirably obtained.

Moreover, the plural second wirings 21 have the wiring length made shorter toward the center side in the aligning direction thereof, and the plural second connections 29 are disposed on the first hypothetical line VL1 and the second hypothetical line VL2 so as to make the wiring resistance of the second wirings 21 higher as the wiring length of the second wirings 21 becomes shorter. With this arrangement, since the plural second connection parts 29 are disposed on the first hypothetical line VL1 and the second hypothetical line VL2 so as to make the wiring resistance higher as the second wirings 21 having a short wiring length, which might cause the generation of an electrostatic breakdown caused by an ESD, becomes further shorter, the occurrence of an electrostatic breakdown can be desirably suppressed.

Moreover, since the plural second wirings 21 have their wiring lengths made shorter toward the center side in the aligning direction thereof, and the plural second connections 29 are disposed on the first hypothetical line VL1 and the second hypothetical line VL2 so as to be formed into straight lines respectively. With this arrangement, the plural second wirings 21 are designed so that the ratios of the respective wiring lengths of the second low resistance wiring part 27 and the second high resistance wiring part 28 occupied in the second wirings 21 are made to change in accordance with the layout in the aligning direction. That is, the plural second wirings 21 are disposed in the center side so that as the wiring length becomes shorter, the ratio of the wiring length of the second high resistance wiring part 28 occupied in the second wirings 21 becomes higher. Thus, even in the case when an ESD is inputted to a second wiring 21 having a short wiring length among the plural second wirings 21, an electrostatic breakdown is hardly generated in a pixel PX or the like connected to the second wirings 21 through the source line 16.

Moreover, the plural second wirings 21 are designed so that one of the second wirings 21A and the other second wiring 21B are alternately disposed side by side. With this arrangement, for example, in the case when the second low resistance wiring part 27 and the second high resistance wiring part 28 are disposed on different layers with an insulating film IN interposed therebetween, even if the array pitch between one of the second wiring 21A and the other adjacent second wiring 21B is made narrower, a short-circuit hardly occurs. Thus, a narrower frame size can be desirably achieved.

Moreover, in the plural second wirings 21, an array in which one of the second wirings 21A and the other second wiring 21B are disposed adjacent to each other is included at least at one portion, and the one of the second wirings 21A and the other second wiring 21B, which are adjacent to each other, are routed along a diagonal direction relative to the aligning direction such that the other end part relative to one of the end parts is biasly located on the center side in the aligning direction of the plural second wirings 21 in the second low resistance wiring part 27 connected to the source line 16 and the second high resistance wiring part 28 connected to the source line 16, and such that the second low resistance wiring part 27 connected to the source line 16 and the second high resistance wiring part 28 connected to the source line 16 are disposed so as not to be overlapped with each other. With this arrangement, when one of the second wirings 21A and the other second wiring 21B are arranged so as to be mutually adjacent to each other, such a positional relationship is formed in which the second low resistance wiring part 27 connected to the source line 16 and the second high resistance wiring part 28 connected to the source line 16 are adjacent to each other, while the second high resistance wiring part 28 connected to the panel side input terminal part 18 and the second low resistance wiring part 27 connected to the panel side input terminal part 18 are adjacent to each other. The second low resistance wiring part 27 that constitutes one of the second wiring 21A and is connected to the source line 16 and the second high resistance wiring part 28 that constitutes the other second wiring 21B and is connected to the source line 16 are respectively routed along a diagonal direction relative to the aligning direction so that the other end part relative to one of the end parts is biasly located to the center side in the aligning direction. Moreover, since the second low resistance wiring part 27 to be connected to the source line 16 and the second high resistance wiring part 28 to be connected to the source line 16 are disposed so as not to be overlapped with each other, in comparison with a case where these are supposedly overlapped with each other, it becomes possible to reduce a parasitic capacitance generated between the two.

Moreover, in the second wirings 21, the second low resistance wiring part 27 or the second high resistance wiring part 28 connected to the source line 16 is routed along a diagonal direction relative to the alignment direction so that the other end part relative to one of end parts is biasly located toward the center side relative to the alignment direction; in contrast, the second high resistance wiring part 28 or the second low resistance wiring part 27 to be connected to the panel side input terminal part 18 is routed linearly along a direction orthogonal to the aligning direction so that one of the end parts is disposed at the same position relative to the aligning direction relative to the other end part. With this arrangement, an array pitch PBi between the adjacent second connection parts 29 relative to the aligning direction can be set to the same as the array pitch Pt between the adjacent panel side input terminal part 18 relative to the aligning direction.

Moreover, the first wiring (second wiring) 20 which is disposed on the end side of the second wiring 21 and whose wiring length is longer than that of the second wiring 21 is installed, and the first wiring 20 is provided with the first low resistance wiring part (second low resistance wiring part) 24 whose one end side is connected to the source line 16 or the panel side input terminal part 18 and the first high resistance wiring (second high resistance wiring part) 25 whose one end side is connected to the panel side input terminal part 18 or the source line 16, and which has a higher resistance than that of the first low resistance wiring part 24 are provided, and the other end sides of the first low resistance wiring part 24 and the first high resistance wiring part 25 are mutually connected by the first connection part (second connection part) 26. With this arrangement, in comparison with the second wiring 21 disposed on the center side, the first wiring 20 disposed on the end side has a longer wiring length from the source line 16 to reach the panel side input terminal part 18, and in contrast, in comparison with the first wiring 20, the second wiring 21 tends to be shorter in the above-mentioned wiring length. On the other hand, the first wiring 20 has a configuration in which the other end parts of the relatively low resistance first low resistance wiring part 24 and the relatively high resistance first high resistance wiring part 25 are connected with each other by the first connection part 26; in contrast, the second wiring 21 has a configuration in which the other end parts of the relatively low resistance second low resistance wiring part 27 and the relatively high resistance second high resistance wiring part 28 are connected with each other by the second connection part 29.

Here, in the case when supposedly, the ratios of the wiring lengths of the first low resistance wiring part 24 and the first high resistance wiring part 25 occupied in the first wiring 20 are made to be equal to each other, while the ratios of the wiring lengths of the second low resistance wiring part 27 and the second high resistance wiring part 28 occupied in the second wiring 21 are made to be equal to each other, since the entire wiring length of the second wiring 21 is shorter than that of the first wiring 20, the entire wiring resistance thereof is lower than that of the first wiring 20. Then, for example, in the case when an ESD (Electro-Static Discharge) is inputted to the first wiring 20 and the second wiring 21, an electrostatic breakdown hardly occurs in the pixel PX or the like connected to the first wiring 20 having a higher wiring resistance, while an electrostatic breakdown easily occurs in the pixel PX or the like connected to the second wiring 21 having a lower wiring resistance.

With respect to this point, the second wiring 21 whose degree of freedom in configuration is enhanced in comparison with that of the prior art is designed so that the ratio of the wiring length in the second high resistance wiring part 28 occupied in the second wiring 21 is set to be higher than the corresponding ratio of the second low resistance wiring part 27; therefore, even when the entire wiring length of the second wiring 21 is shorter than that of the first wiring 20, it becomes possible to prevent the wiring resistance relating to the second wiring 21 from becoming too low. Therefore, even in the case when an ESD is inputted to the second wiring 21, an electrostatic breakdown hardly occurs in the pixel PX or the like connected to the second wiring 21 through the source line 16. When an electrostatic breakdown hardly occurs in the pixel PX or the like connected to the second wiring 21 through the source line 16, it becomes unnecessary, for example, to connect an ESD protection circuit to the second wiring 21, and even in the case when, for example, the ESD protection circuit is connected, it is only necessary to use a simple, small-size ESD protection circuit. Thus, since the layout space for the second wiring 21 can be reduced, a narrower frame size can be desirably achieved.

Moreover, in the first wiring 20, the first low resistance wiring parts 24 or the first high resistance wiring parts 25 a plurality of which are disposed in parallel with one another and connected to the source line 16 are routed along a diagonal direction relative to the aligning direction such that the other end part relative to one of the end parts is biasly located on the center side with respect to the aligning direction of the first wiring 20, while the first high resistance wiring parts 25 or the first low resistance wiring parts 24 to be connected to the panel side input terminal part 18 is routed along a diagonal direction relative to the aligning direction such that one of end parts relative to the other end part is biasly located on the center side relative to the aligning direction, with the array pitch PAi of the plural first connection parts 26 being made narrower than the lead-out pitch P, and with those parts being shifted toward the source line 16 side as those are disposed closer to the center side relative to the aligning direction. With this arrangement, in the plural first wirings 20, the first low resistance wiring parts 24 or the first high resistance wiring parts 25 to be connected to the source line 16, and the first high resistance wiring parts 25 or the first low resistance wiring parts 24 to be connected to the panel side input terminal part 18 are respectively routed along a diagonal direction, with the array pitch PAi of the plural first connection parts 26 being made narrower than the lead-out pitch P; therefore, the layout space for the plural first wirings 20 can be made smaller. Thus, a narrower frame size can be desirably achieved. In addition to this, since the plural first connection parts 26 are disposed so as to be shifted toward the source line 16 side as those parts are disposed closer to the center side with respect to the aligning direction, a desirable configuration is formed in adjusting the array pitch d1 or d2 between the adjacent first wirings 20 and in adjusting the angle θ1 or θ2 made by the first low resistance wiring parts 24 or the high resistance wiring parts 25 relative to the aligning direction.

Moreover, in the plural first wirings 20, the array pitch d1 between the first low resistance wiring parts 24 or first high resistance wiring parts 25 that are connected to the source line 16 and made adjacent with each other in the aligning direction and the array pitch d2 between the first high resistance wiring parts 25 or first low resistance wiring parts 24 that are connected to the panel side input terminal part 18 and made adjacent with each other in the aligning direction are equal to each other. With this arrangement, the array pitch d1 or d2 between the adjacent first wirings 20 from the source line 16 to reach the panel side input terminal part 18 can be uniformed so that the plural first wirings 20 can be effectively routed out. Thus, a narrower frame size can be further desirably achieved.

Furthermore, in the plural first wirings 20, the angle θ1 made by the first low resistance wiring parts 24 or the first high resistance wiring parts 25 that are connected to the source line 16 relative to the aligning direction and the angle θ2 made by the first high resistance wiring parts 25 or the first low resistance wiring parts 24 that are connected to the panel side input terminal part 18 relative to the aligning direction are equal to each other. With this arrangement, in the plural first wirings 20, the first low resistance wiring part 24 or the first high resistance wiring part 25 to be connected to the source line 16 and the first high resistance wiring part 25 or the first low resistance wiring part 24 to be connected to the panel side input terminal part 18 are made in parallel with each other; therefore, the plural first wirings 20 can be effectively routed out. Thus, a narrower frame size can be further desirably achieved.

Moreover, the first high resistance wiring part 25 and the second high resistance wiring part 28 are made of a first metal film (first conductive film) Ml, while the first low resistance wiring part 24 and the second low resistance wiring part 27 are disposed on a layer different from the first metal film M1 with an insulating film IN interposed therebetween, and made of a second metal film (second conductive layer) M2 having a sheet resistance lower than that of the first metal film M1. With this arrangement, in comparison with a case where supposedly, the first high resistance wiring part and the second high resistance wiring part, as well as the first low resistance wiring part and the second high resistant wiring part, are disposed on the same layer, the degree of freedom relating to the plane layout of the first low resistance wiring part 24, the first high resistance wiring part 25, the second low resistance wiring part 27 and the second high resistance wiring part 28 becomes higher. Thus, a narrower frame size can be further desirably achieved. Moreover, since the sheet resistances between the first metal film M1 and the second metal film M2 are made different from each other, the degree of freedom relating to the width dimension and thickness of the first low resistance wiring part 24, the first high resistance wiring part 25, the second low resistance wiring part 27 and the second high resistance wiring part 28 can be enhanced.

Moreover, a liquid crystal panel (display panel) 11 in accordance with the present embodiment is provided with the above-mentioned array substrate 11B and a CF substrate (opposing substrate) 11A to be bonded to the array substrate 11B. In accordance with the liquid crystal panel 11 having such a configuration, since a narrower frame size of the array substrate 11B can be achieved, higher designing function can be obtained.

### Second Embodiment

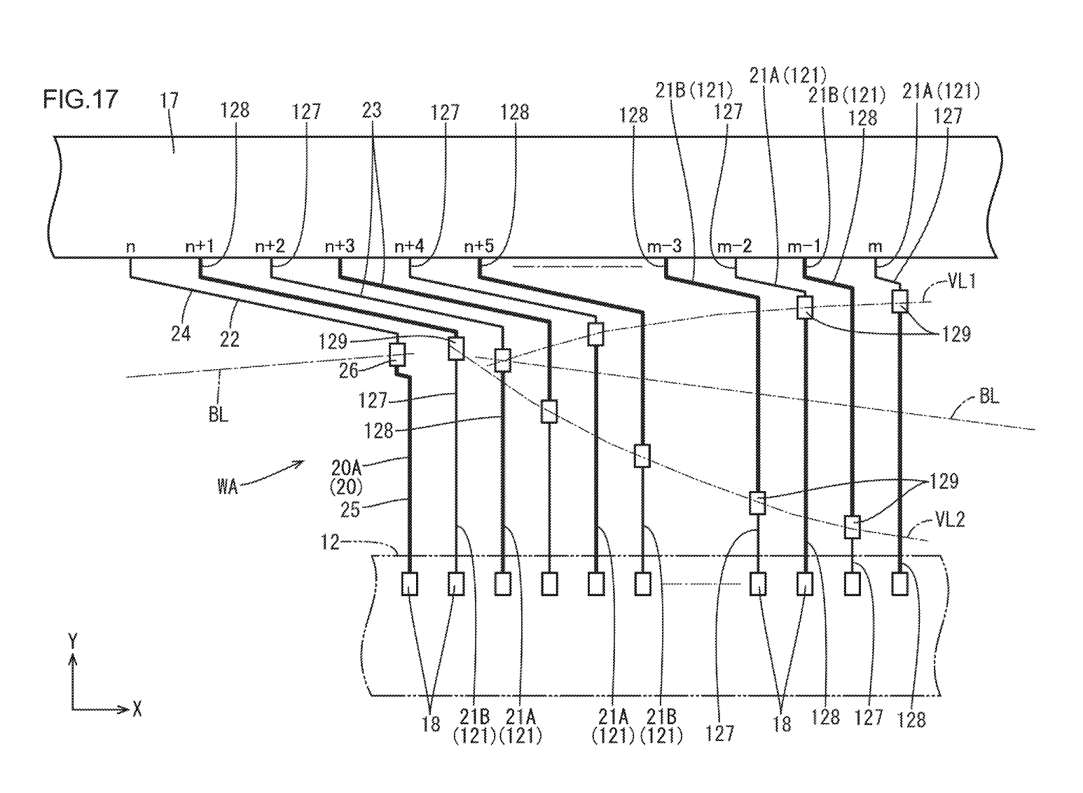

Referring to FIG. 17, explanation will be given on a second embodiment. In the second embodiment, a configuration in which the layout of the second connection part 129 is altered is shown. Additionally, with respect to the same configuration, functions and effects as those of the above-mentioned first embodiment, overlapped explanations will be omitted.

As shown in FIG. 17, a plurality of connection parts 129 in accordance with the present embodiment are disposed such that a first hypothetical line VL1 and a second hypothetical line VL2 are respectively formed into curves. Each of the first hypothetical line VL1 and the second hypothetical line VL2 has an arch shape that gradually extends onto a side opposite to the reference hypothetical line BL side, with its center of curvature being disposed on the reference hypothetical line BL side. With this arrangement, in the plural second wirings 121, the ratio of the respective wiring lengths of the second low resistance wiring part 127 and the second high resistance wiring part 128 occupied in the second wiring 121 is allowed to change freely depending on the layout in the X-axis direction. That is, in the plural second wirings 121, as the wiring length becomes shorter while being disposed closer to the center side, the ratio of the wiring length of the second high resistance wiring part 128 occupied in the plural second wirings 121 becomes higher. Thus, even in the case when an ESD is inputted to the second wiring 121 whose wiring length is shorter among the plural second wirings 121, it becomes possible to make an electrostatic breakdown hardly occur in the TFT or the like constituting the pixel connected to the second wiring 121 through the source line.

As described above, in accordance with the present embodiment, the plural second connection parts 129 are disposed so as to make the first hypothetical line VL1 and the second hypothetical line VL2 respectively form curves. With this arrangement, in the plural second wirings 121, the ratios of the respective wiring lengths of the second low resistance wiring part 127 and the second high resistance wiring part 128 occupied in the second wirings 121 is allowed to change freely depending on the layout in the aligning direction. That is, in the plural second wirings 121, the ratio of the wiring length of the second high resistance wiring part 128 occupied in the second wirings 121 becomes higher as the wiring length becomes shorter, while being disposed on the center side. Thus, even in the case when an ESD is inputted to the second wiring 121 whose wiring length is shorter among the plural second wirings 121, it becomes possible to make an electrostatic breakdown hardly occur in the pixel or the like connected to the second wiring 121 through the source line.

### Third Embodiment

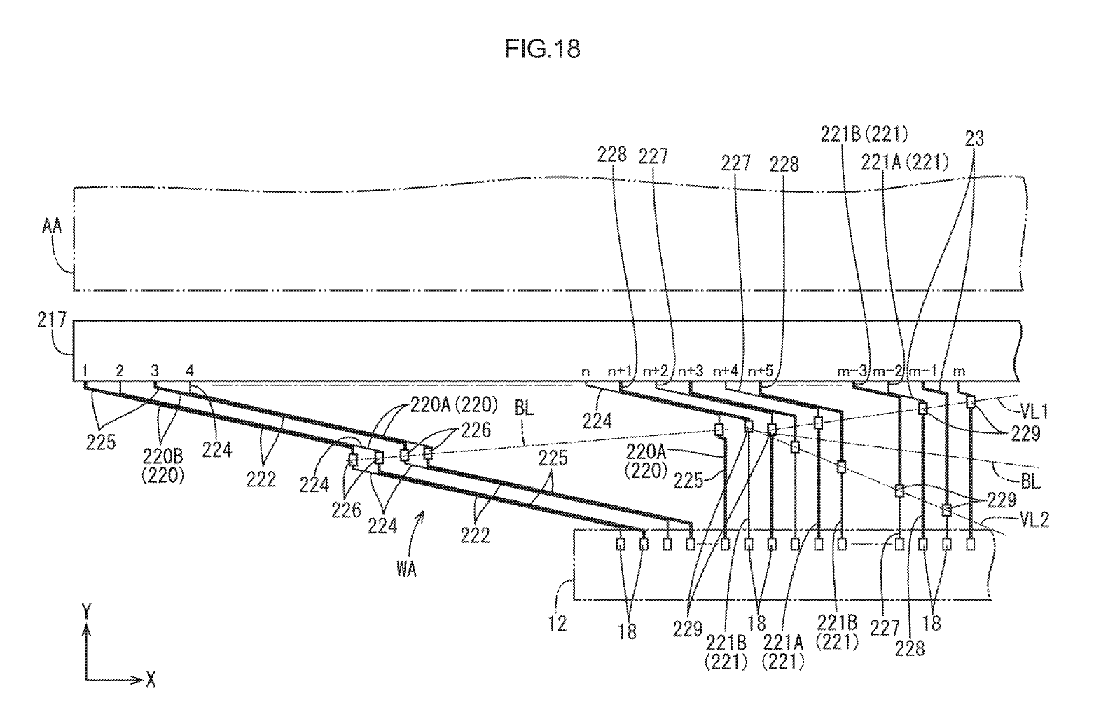

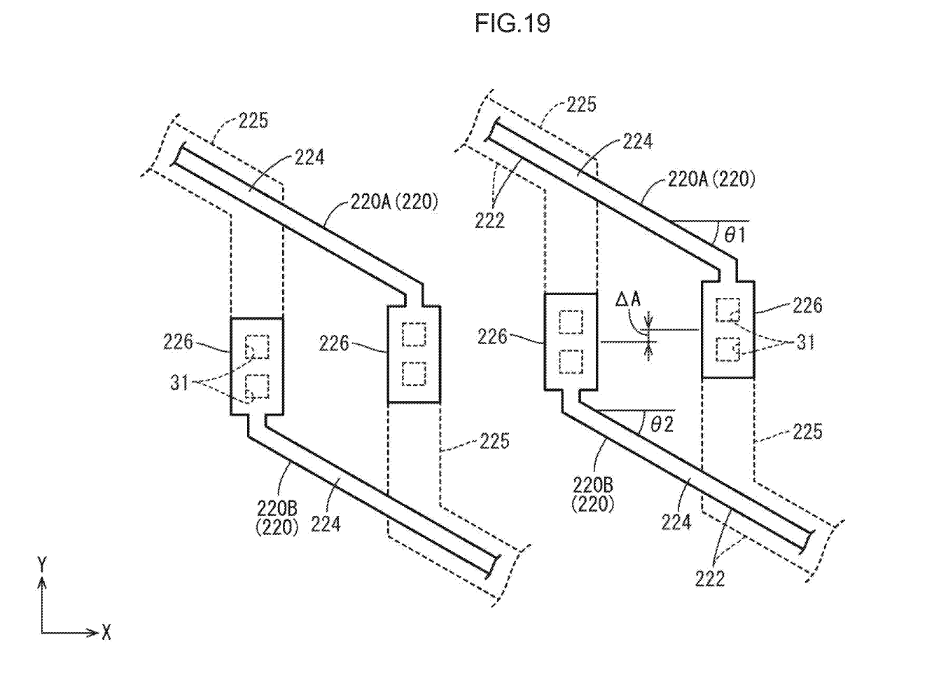

Referring to FIG. 18 or FIG. 19, explanation will be given on a third embodiment of the present invention. In the third embodiment, a configuration in which structures of first wirings 220 and second wirings 221 are altered from those of the above-mentioned first embodiment is shown. Additionally, with respect to the same configuration, functions and effects as those of the above-mentioned first embodiment, overlapped explanations will be omitted.

As shown in FIG. 18, one of second wirings 221A and the other second wiring 221B, which constitute a plurality of the second wirings 221 relating to the present embodiment, are disposed such that a second low resistance wiring part 227 and a second high resistance wiring part 228 respectively connected to the source line (not shown in the present embodiment) through source input parts 217 are disposed so as to be overlapped with each other with an insulating film interposed therebetween. With this arrangement, in comparison with a case in which supposedly, the second low resistance wiring part that constitutes one of the second wiring 221A and is connected to the source line through the source input part 217 and the second high resistance wiring part that constitutes the other second wiring 221B and is connected to the source line through the source input part 217 are disposed so as not to be overlapped with each other, the second wiring 221 can be routed out from one of end parts to the other end part with a smaller angle. Thus, a narrower frame size can be desirably obtained. In the same manner, as shown in FIG. 18 and FIG. 19, one of first wirings 220A and the other first wiring 220B, which constitute a plurality of first wirings 220, are disposed such that a first low resistance wiring part 224 and a first high resistance wiring part 225 respectively connected to the source line through the source input parts 217 are disposed so as to be overlapped with each other with an insulating film interposed therebetween. Therefore, an angle θ1 or θ2 made by a first diagonally extending part 222 possessed by the first high resistance wiring part 225 or the first low resistance wiring part 224 relative to the X-axis direction can be made smaller. With respect to a value of distance (shift amount) ΔA in the Y-axis direction between first connection parts 226 adjacent to each other in the X-axis direction, readjustment can be desirably made. Moreover, the layout configuration of the second low resistance wiring part 227 and the second high resistance wiring part 228 that constitute the second wirings 221 and are overlapped with each other is substantially the same as that of the first wiring 220 shown in FIG. 19.

As explained above, in accordance with the present embodiment, the plural second wirings 221 include an array in which one of the second wirings 221A and the other second wiring 221B are adjacent with each other, at least at one portion, and the one of the second wirings 221A and the other second wiring 221B mutually adjacent to each other are routed along a diagonal direction relative to the aligning direction such that the other end part relative to one of end parts are respectively located biasly on the center side relative to the aligning direction in the second low resistance wiring part 227 connected to the source line and the second high resistance wiring part 228 connected to the source line, with the second low resistance wiring part 227 connected to the source line and the second high resistance wiring part 228 connected to the source line being overlapped with each other with an insulating film interposed therebetween. With this arrangement, in the case when the one of the second wirings 221A and the other second wiring 221B are arranged adjacent to each other, such positional relationships are formed in which the second low resistance wiring part 227 to be connected to the source line and the second high resistance wiring part 228 to be connected to the source line are made adjacent to each other and the second high resistance wiring part 228 to be connected to the panel side input terminal part 218 and the second low resistance wiring part 227 to be connected to the panel side input terminal part 218 are made adjacent to each other. The second low resistance wiring part 227 that forms one of the second wirings 221A and is connected to the source line and the second high resistance wiring part 228 that forms the other second wiring 221B and is connected to the source line are respectively routed along a diagonal direction relating to the aligning direction such that the other end part relative to the one of end parts is located biasly on the center side in the aligning direction. Moreover, since the second low resistance wiring part 227 to be connected to the source line and the second high resistance wiring part 228 to be connected to the source line are disposed so as to be overlapped with each other with an insulating film interposed therebetween, these can be routed out from one of the end parts to the other end part with a smaller angle in comparison with the case in which the non-overlapped state is supposedly formed. Thus, a narrower frame size can be more desirably achieved.

### Fourth Embodiment

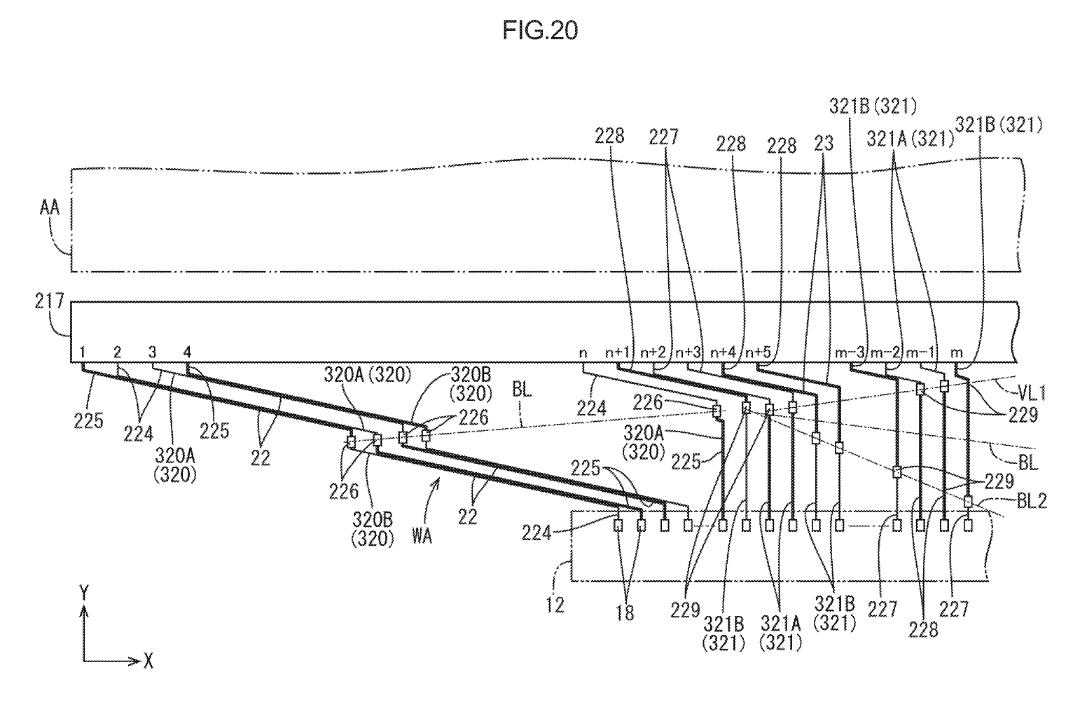

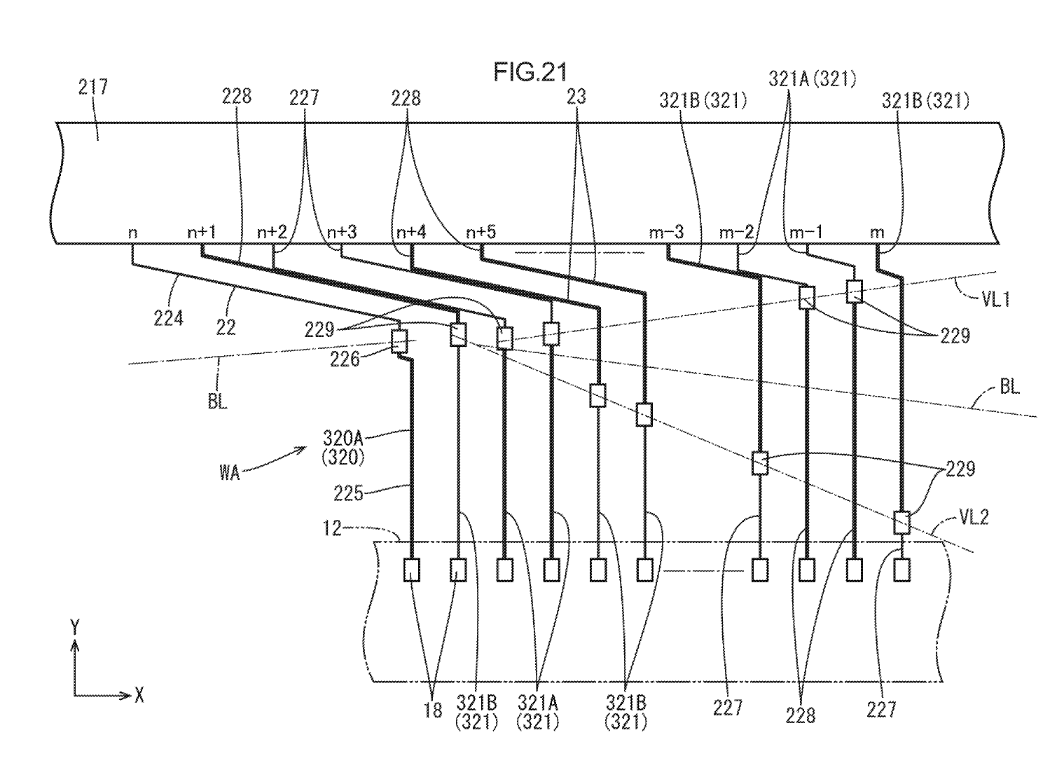

Referring to FIG. 20 or FIG. 21, explanation will be given on a fourth embodiment of the present invention. In the fourth embodiment, a configuration in which structures of the first wirings 320 and second wirings 321 are altered from those of the above-mentioned third embodiment is shown. Additionally, with respect to the same configuration, functions and effects as those of the above-mentioned third embodiment, overlapped explanations will be omitted.

As shown in FIG. 20 and FIG. 21, a plurality of first wirings 320 relating to the present embodiment include an array in which one of the first wirings 320A and the other first wirings 320B are successively arranged two by two in parallel with one another. More specifically, one of the first wirings 320A is disposed at the second, the third, the sixth, the seventh . . . (n−3)th, and n-th places, while the other first wirings 320B is disposed at the first, the fourth, the fifth, the eighth . . . (n−2)th, and (n−1)th places. In the same manner, a plurality of second wirings 321 include an array in which one of the first wirings 321A and the other first wirings 321B are successively arranged two by two in parallel with one another. More specifically, one of the second wirings 321A is disposed at the (n+2)th, (n+3)th, . . . (m−2)th, and (m−1)th places, while the other second wiring 321B is disposed at the (n+1)th, (n+4)th, (n+5)th, . . . , (m−4)th, (m−3)th, and the m-th places. With this arrangement, it is possible to enhance the degree of freedom in arranging the first wirings 320 and the second wirings 321, with a plurality thereof being disposed.

As explained above, in accordance with the present embodiment, with respect to the plural second wirings 321, a plurality of pairs of the one of the second wirings 321A or the other second wirings 321B are disposed in parallel with one another. With this arrangement, it is possible to enhance the degree of freedom in arranging the plural second wirings 321.

### Other Embodiments

The present invention is not intended to be limited to the embodiments described above with reference to the drawings. The following embodiments may be included in the technical scope.

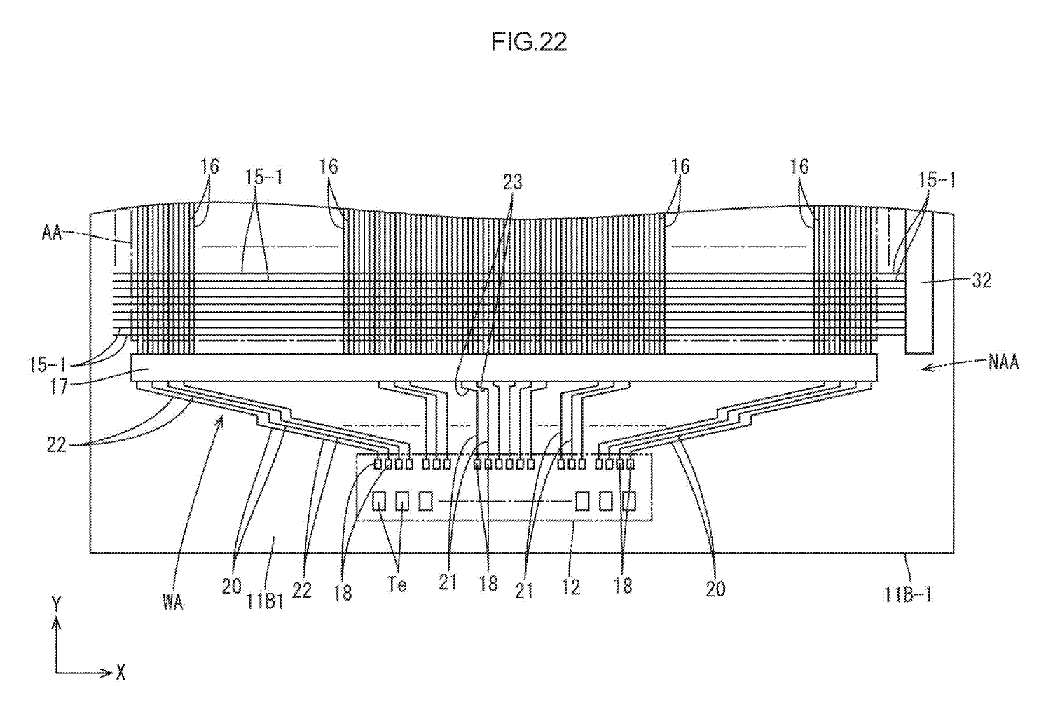

(1) As shown in FIG. 22, as first modified example, in the non-display area NAA of the array substrate 11B-1, a gate circuit part 32 for supplying a scanning signal to a gate line 15-1 may be installed. The gate circuit part 32 may be disposed so as to be adjacent to one side of the display area AA in the X-axis direction and extends along all the entire length of the display area AA in the Y-axis direction.

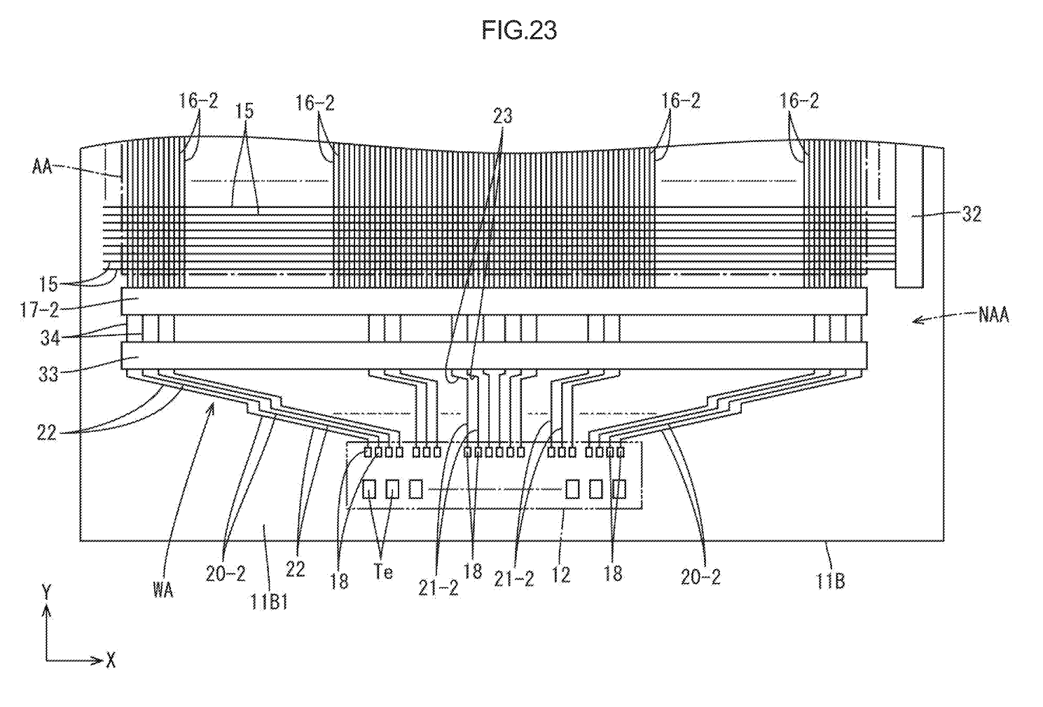

(2) As shown in FIG. 23, as second modified example of the above-mentioned first modified example, between the source circuit part 17-2 and the terminal area WA, a source protection circuit part 33 having an ESD protection circuit may be installed. By the source protection circuit part 33, it becomes to more positively prevent an electrostatic breakdown in the pixel. To the source protection circuit part 33, one of the end parts of each of the first wiring 20-2 and the second wiring 21-2 is connected. Between the source protection circuit part 33 and the source circuit part 17-2, a connection wiring 34 that connects the two parts with each other is installed. The first wiring 20-2 and the second wiring 21-2 are indirectly connected to a source line 16-2 through the source protection circuit part 33, the connection wiring 34 and the source circuit part 17-2.

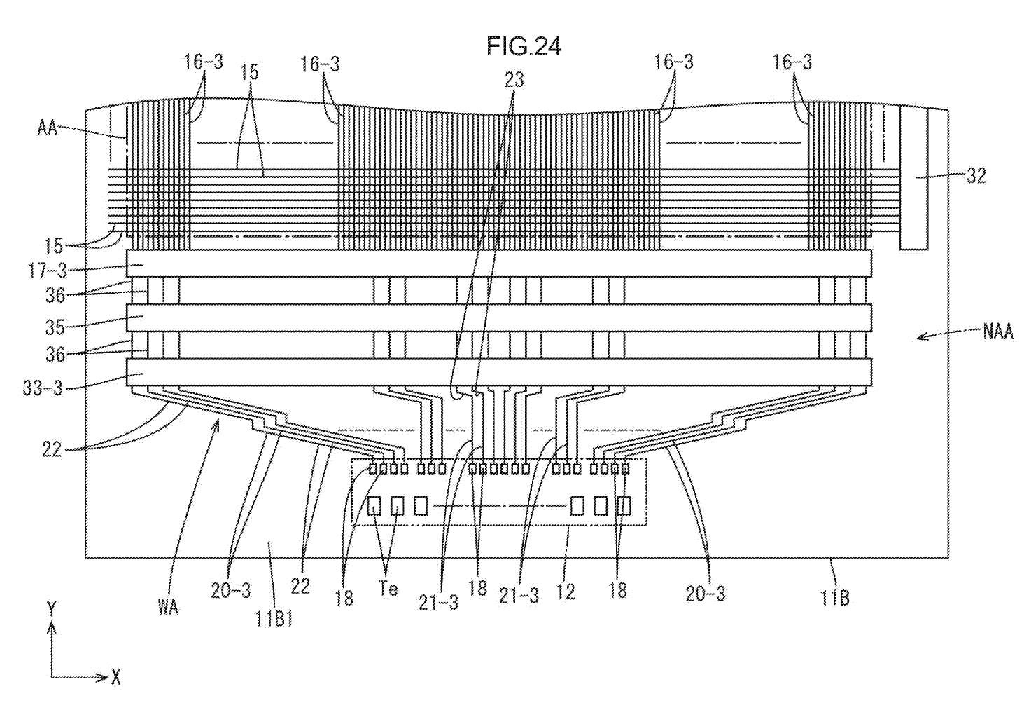

(3) As shown in FIG. 24, as third modified example of the above-mentioned second modified example, between the source circuit part 17-3 and the terminal area WA, a source detection circuit part 35 may be installed in addition to the source protection circuit part 33-3 described in the above-mentioned second modified example. The source detection circuit part 35, which is interposed between the source protection circuit part 33-3 and the source circuit part 17-3, is connected to the two parts respectively by connection wirings 36. The first wiring 20-3 and the second wiring 21-3 are indirectly connected to the source line 16-3 through the source protection circuit part 33-3, the connection wiring 36, the source detection circuit part 35, the connection wiring 36 and the source circuit part 17-3.

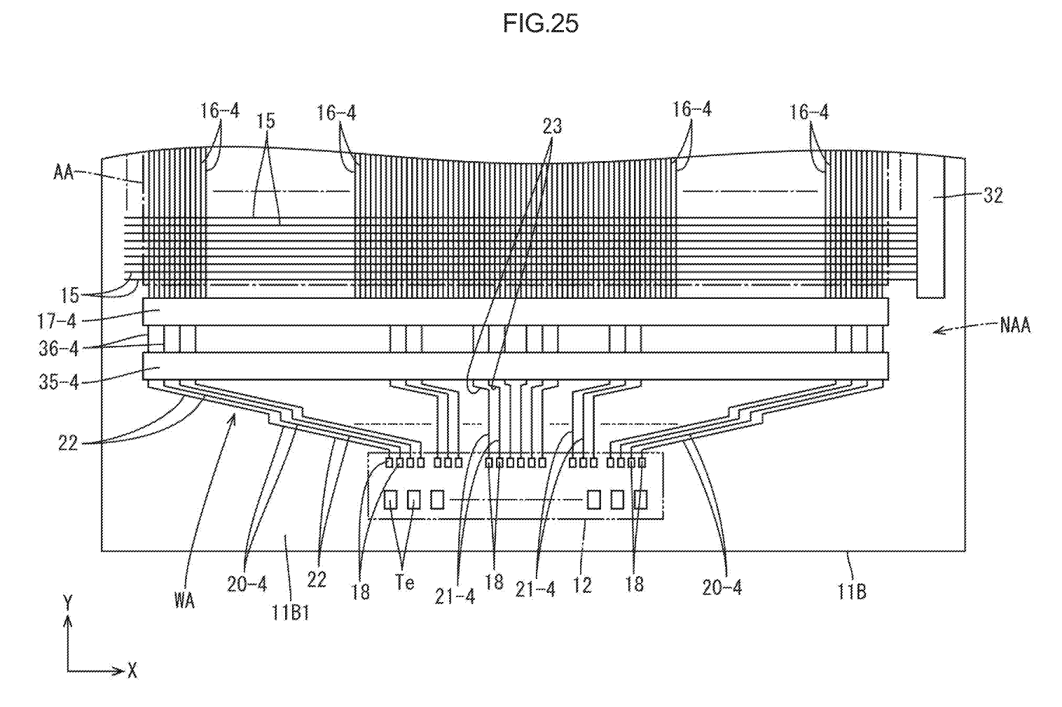

(4) As shown in FIG. 25, as fourth modified example of the above-mentioned second modified example, in place of the source protection circuit part 33, a source detection circuit part 35-4 may be installed. The source detection circuit part 35-4 is the same as that described in the above-mentioned third modified example. The first wiring 20-4 and the second wiring 21-4 are indirectly connected to the source line 16-4 through the source detection circuit part 35-4, the connection wiring 36-4 and the source circuit part 17-4.

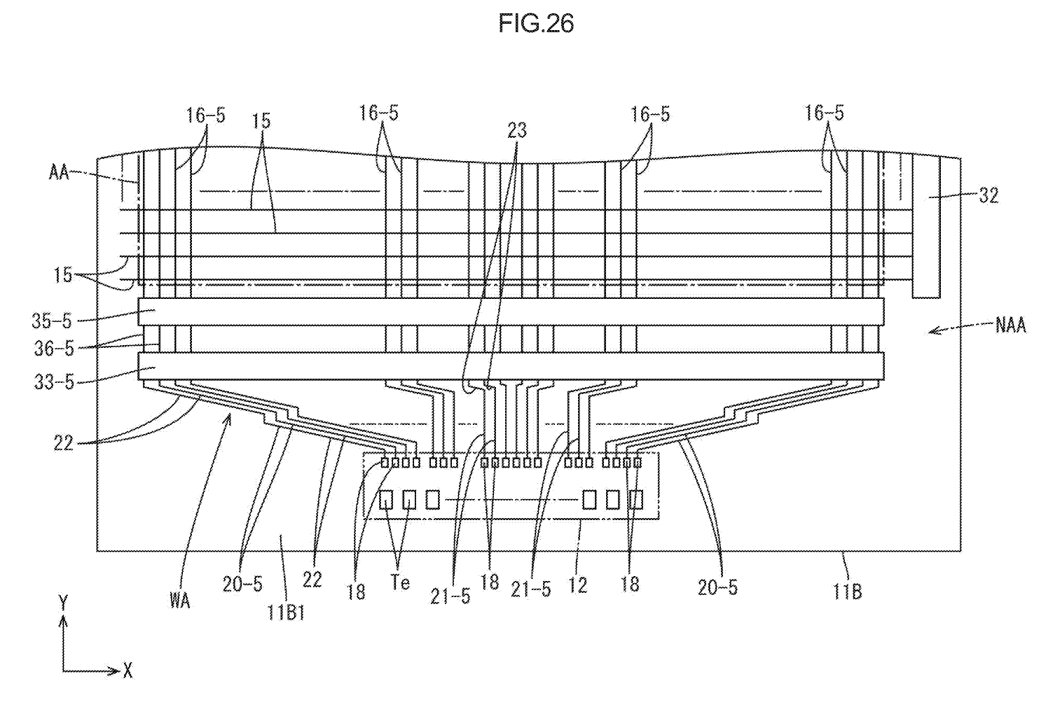

(5) As shown in FIG. 26, as fifth modified example of the above-mentioned third modified example, the source circuit part 17-3 (see FIG. 24) described in the third modified example may be omitted. In accordance with this arrangement, the installation number of the first wirings 20-5 and the second wirings 21-5 is equal to the installation number of the source lines 16-5. The first wiring 20-5 and the second wiring 21-5 are indirectly connected to the source line 16-5 through the source protection circuit part 33-5, the connection wiring 36-5 and the source detection circuit part 35-5.

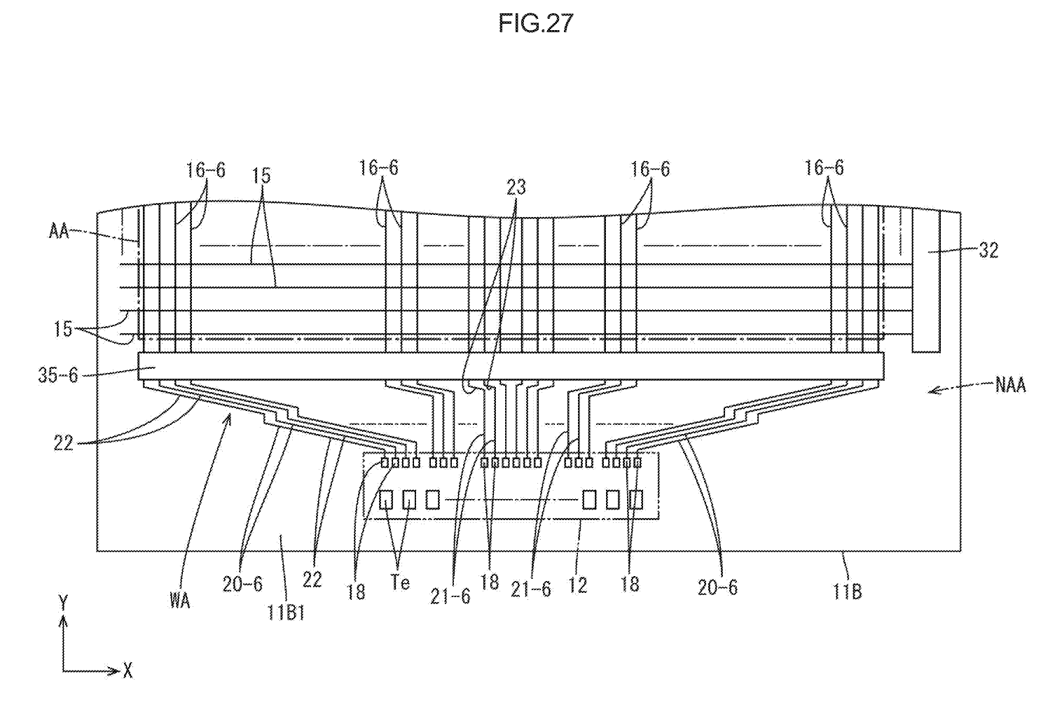

(6) As shown in FIG. 27, as sixth modified example of the above-mentioned fifth modified example, the source protection circuit part 33-5 and the connection wiring 36-5 (see FIG. 26) described in the fifth modified example may be omitted. The first wiring 20-6 and the second wiring 21-6 are indirectly connected to the source line 16-6 through the source detection circuit part 35-6.

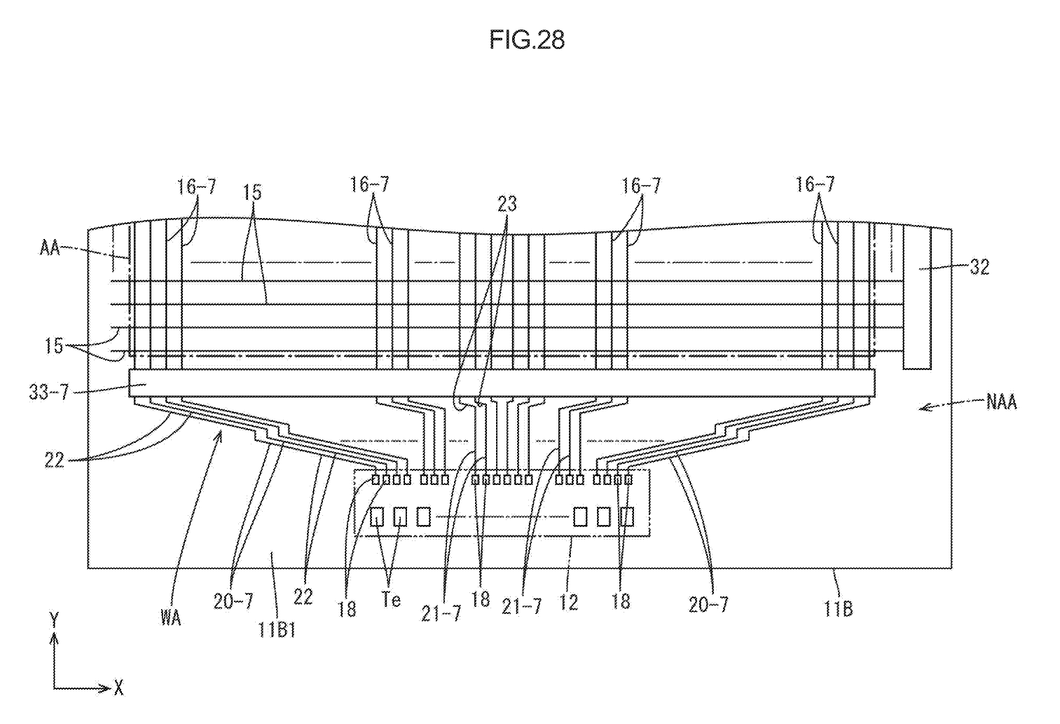

(7) As shown in FIG. 28, as seventh modified example of the above-mentioned fifth modified example, the source detection circuit part 35-5 and the connection wiring 36-5 (see FIG. 26) described in the fifth modified example may be omitted. The first wiring 20-7 and the second wiring 21-7 are indirectly connected to the source line 16-7 through the source protection circuit part 33-7.

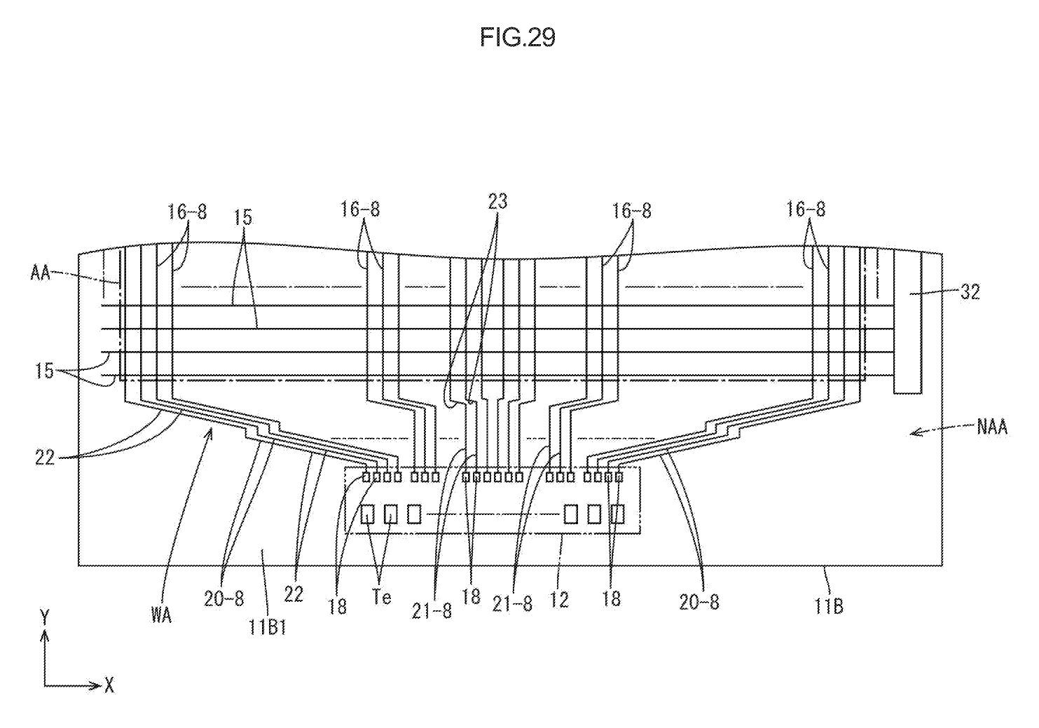

(8) As shown in FIG. 29, as eighth modified example of the above-mentioned fifth modified example, the source protection circuit part 33-5, the source detection circuit part 35-5 and the connection wiring 36-5 (see FIG. 26) described in the fifth modified example may be omitted. The first wiring 20-8 and the second wiring 21-8 are directly connected to the source line 16-8.

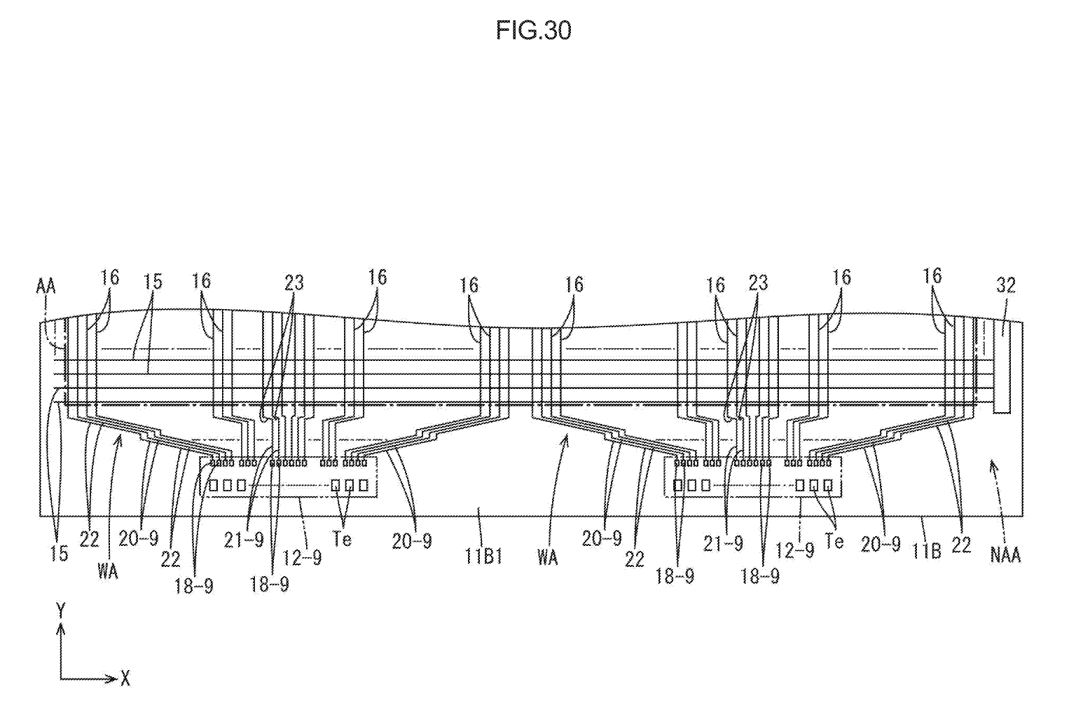

(9) As shown in FIG. 30, as ninth modified example of the above-mentioned eighth modified example, two drivers 12-9 may be installed. The two drivers 12-9 are disposed at positions spaced from each other in the X-axis direction, and in their respective assembling areas, plural pieces of panel side input terminal parts 18-9 connected to first wirings 20-9 and second wirings 21-9 are installed. Two terminal areas WA in which the first wirings 20-9 and the second wirings 21-9 are disposed at positions spaced apart from each other in the X-axis direction.

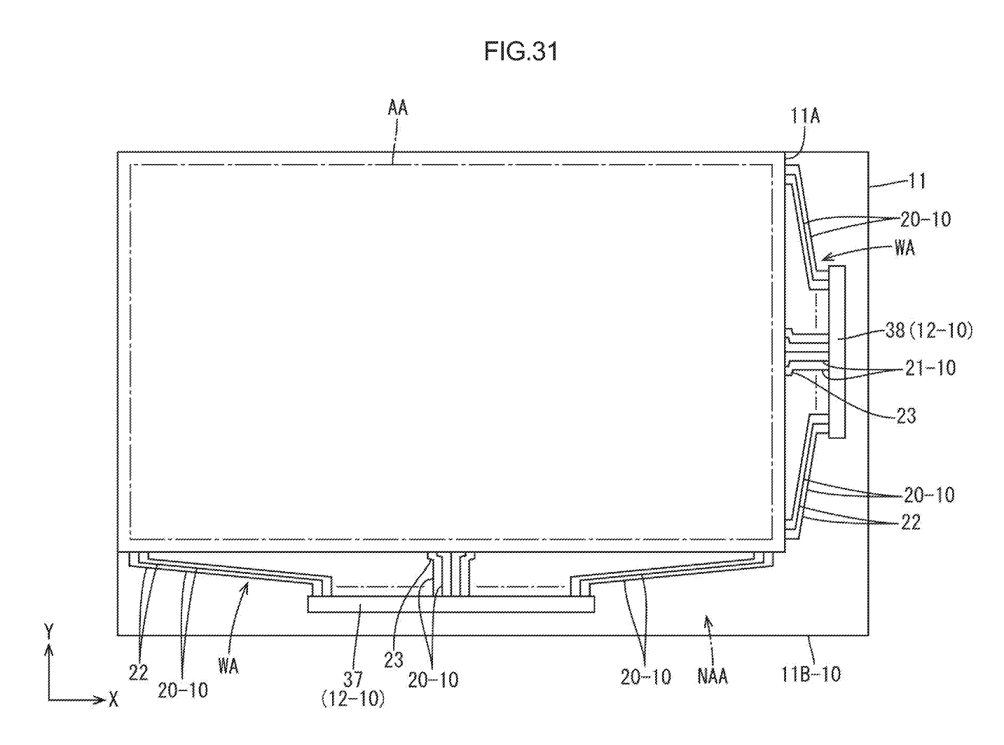

(10) As shown in FIG. 31, as tenth modified example of the above-mentioned eighth modified example, as tenth modified example of the above-mentioned eighth modified example, drivers 12-10 may be installed on a long side part and a short side part of an array substrate 11B-10. The driver installed on the long side part of the array substrate 11B-10 is a source driver 37 to be connected to the source line, and the driver installed on the short side part of the array substrate 11B-10 is a gate driver 38 to be connected to the gate line (not shown, together with the source line). The panel side input terminal part and the source line disposed in the assembling area of the source driver 37 are connected with each other by first wiring 20-10 and second wiring 21-10. In the same manner, the panel side input terminal part and the gate line disposed in the assembling areas of the gate driver 38 are connected to each other by the first wiring 20-10 and the second wiring 21-10.

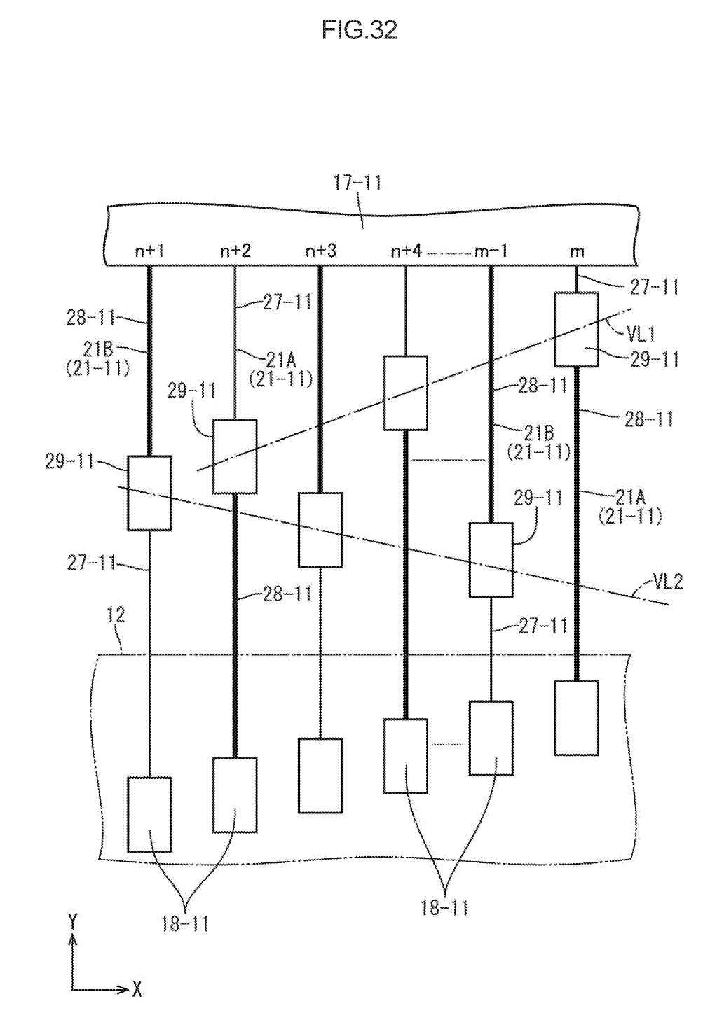

(11) As shown in FIG. 32, as modified example 11, a plurality of second wirings 21-11 may have a configuration in which a plurality of second wirings 21-11 are linearly extended without being bent in the mid way from the source circuit part 17-11 to reach the panel side input terminal part 18-11. With respect to the plural panel side input terminal parts 18-11 connected to the second wiring 21-11 having this configuration, those which are disposed closer to the end side in the X-axis direction are disposed at a position farther from the source circuit part 17-11 in the Y-axis direction, while those which are disposed closer to the center side in the X-axis direction are disposed at a position closer to the source circuit part 17-11 in the Y-direction. By disposing the plural panel side input terminal parts 18-11 in this layout, the plural second wirings 21-11 tend to have shorter wiring length as those are disposed closer to the center side in the X-axis direction, while they tend to have longer wiring length as those are disposed closer to the end side. That is, in a configuration in which the distance between the source circuit part 17-11 and the panel side input terminal part 18-11 is changed in accordance with the position in the X-axis direction, the wiring length of the plural second wirings 21-11 does not necessarily depend on a route as to how it is bent in the mid way and disposed. Moreover, the disposed state of the second connection part 29-11 is determined so that as the second wiring 21-11 disposed in the center position in the X-axis direction has a shorter wiring length, the ratio of the wiring length of the second high resistance wiring part 28-11 occupied in the second wiring 21-11 becomes higher; in contrast, as the second wiring 21-11 disposed closer to the end side in the X-axis direction has a longer wiring length, the ratio of the wiring length of the second high resistance wiring part 28-11 occupied in the second wiring 21-11 becomes lower. More desirably, the disposed state of the second connection part 29-11 is determined so that the ratio of the wiring length of the second high resistance wiring part 28-11 occupied in the second wiring 21-11 is made highest in the second wiring 21-11 disposed at a position closest to the center side in the X-axis direction with the shortest wiring length and so that in contrast, it is made lowest in the second wiring 21-11 disposed at a position closest to the end side in the X-axis direction with the longest wiring length.

(12) The above-mentioned respective embodiments have exemplified a case in which the second connection part is respectively formed on the first hypothetical line and the second hypothetical line; however, the second connection part may be formed on either the first hypothetical line or the second hypothetical line.

(13) The specific plane shape of the first hypothetical line and the second hypothetical line may be altered on demand.

(14) The order of arrangements, the number of arrangements or the like of one of the second wirings and the other second wiring constituting the second wirings may be altered on demand. In the same manner, the order of arrangements, the number of arrangements or the like of one of the first wirings and the other first wiring constituting the first wirings may be altered on demand.

(15) The specific size relation ship, such as the array pitch of the source lines, the specific size relationship of the array pitch of the first connection parts, the array pitch of the second connection parts, the array pitch of the first wirings, the array pitch of the second wirings, the array pitch of the panel side input terminal parts or the like may be altered on demand.

(16) The angle made by the first diagonally extending part possessed by the first wiring relative to the X-axis direction and the angle made by the second diagonally extending part possessed by the second wiring relative to the X-axis direction may be altered on demand.

(17) The specific wiring route of the first wiring and the second wiring may be altered on demand.

(18) The ratio of the line widths between the respective low resistance wiring parts and the respective high resistance wiring parts may be altered on demand. The respective low resistance wiring parts and the respective high resistance wiring parts may be set to the same width.

(19) The respective low resistance wiring parts and the respective high resistance wiring parts may be made of metal films of the same material. In this case, the resistance values may be made different from each other to high and low levels by making the line width and thickness between the respective low resistance wring parts and the respective high resistance wiring parts different from each other. Moreover, the respective low resistance wiring parts and the respective high resistance wiring parts are desirably made on different layers; however, the present invention is not intended to be limited thereby.

(20) The respective low resistance wiring parts and the respective high resistance wiring parts may be made of metal films disposed on the same layer. In this case, the materials for the metal films disposed on the same layer may be made different from each other, or may be the same.

(21) Three or more drivers to be connected to the source line may be assembled. Moreover, a plurality of the gate drivers described in the tenth modified example may be installed.

(22) Another configuration in which the drivers are COF (Chip On Film)-assembled on the array substrate may be used. In this case, the first wirings and the second wirings are connected to an external connection terminal part (signal input part) disposed on the assembling area of the flexible substrate of the array substrate.

(23) The present invention may be applied to a liquid crystal panel having a longitudinally long square shape or a liquid crystal panel having a square shape. In addition to this, the present invention may be applied to a liquid crystal panel having a round shape or an elliptical shape.

(24) The present invention may be applied to a reflection type liquid crystal device that performs display by utilizing an external light source, and in this case, the back light device can be omitted. Moreover, the present invention may be applied to a semi-transmission type liquid crystal device.

(25) The above-mentioned respective embodiments have exemplified a case in which a TFT is used as the switching element of a liquid crystal device; however, the present invention may be applied to a liquid crystal device using a switching element other than a TFT (for example, thin-film diode (TFD)), and in addition to the liquid crystal display that performs color display, the present invention may also be applied to a liquid crystal display that performs black/white display.

(26) The above-mentioned respective embodiments have exemplified a liquid crystal display using a liquid crystal panel as a display panel; however, the present invention may be applied to a display device using a display panel of other kinds (such as PDP (plasma display panel), organic EL panel, EPD (display panel of micro-capsule type electrophoretic system), MEMS (Micro Electro Mechanical Systems) display panel or the like).

1. An active matrix substrate:
pixels;
a pixel wiring connected to the pixels;
a signal input part for inputting a signal to the pixel wiring;
a wiring connected to the pixel wiring and the signal input part;
a low resistance wiring part that constitutes the wiring and has one end side thereof connected to the pixel wiring or the signal input part;
a high resistance wiring part that constitutes the wiring and has one end side thereof connected to the signal input part or the pixel wiring, and has resistance higher than that of the low resistance wiring part, with a ratio of a wiring length occupied in the wiring being made higher than that of the low resistance wiring part; and
a connection part that connects other end sides of the low resistance wiring part and the high resistance wiring part to each other.

2. The active matrix substrate according to claim 1, further comprising:
a second wiring that is disposed on an end side of said wiring and has a wiring length longer than that of said wiring,
wherein the second wiring has a low resistance wiring part that has one end side thereof connected to the pixel wiring or the signal input part; a high resistance wiring part that has one end side thereof connected to the pixel wiring or the signal input part, and has resistance higher than that of the low resistance wiring part, with the other end sides between the second low resistance wiring part and the second high resistance wiring part being connected to each other by a second connection part.

3. The active matrix substrate according to claim 1, wherein a plurality of the second wirings are disposed in parallel with one another and the second low resistance wiring part or the second high resistance wiring part to be connected to the pixel wirings is routed in a diagonal direction relative to the aligning direction such that the other end side relative to the one end side is biasly located on the center side relative to the aligning direction of the second wiring; in contrast, the second high resistance wiring part or the second low resistance wiring part to be connected to the signal input part is routed in a diagonal direction relative to the aligning direction such that the one end side relative to the other end side is biasly located on the center side relative to the aligning direction, and wherein the plural second connection parts have the array pitch thereof made narrower than the array pitch of the plural pixel wirings and as those parts are disposed closer to the center side relative to the aligning direction, they are further shifted toward the pixel wiring side.

4. The active matrix substrate according to claim 3, wherein with respect to the second wirings, an array pitch between the second low resistance wiring parts or the second high resistance wiring parts that are connected to the pixel wirings and are adjacent to each other in the aligning direction and an array pitch between the second high resistance wiring parts or the second low resistance wiring parts that are connected to the signal input parts and are adjacent to each other in the aligning direction are made equal to each other.

5. The active matrix substrate according to claim 3, wherein with respect to the plural second wirings, an angle made by the second low resistance wiring parts or the second high resistance wiring parts that are connected to the pixel wirings relative to the aligning direction and an angle made by the second high resistance wiring parts or the second low resistance wiring parts relative to the aligning direction are made equal to each other.

6. The active matrix substrate according to claim 2, wherein the high resistance wiring part and the second high resistance wiring part are made of a first conductive film, while the low resistance wiring part and the second low resistance wiring part are disposed on a layer different from the first conductive film with an insulating film interposed therebetween, and made of a second conductive film having a sheet resistance lower than that of the first conductive film.

7. The active matrix substrate according to claim 1, wherein a plurality of the wirings are disposed in parallel with one another, and one of the wirings to which the low resistance wiring part connected to the pixel wiring and the high resistance wiring part connected to the signal input part are connected by the connection part and the other wiring to which the high resistance wiring part connected to the pixel wiring and the low resistance wiring part connected to the signal input part are connected by the connection part are included therein, and wherein a plurality of the connection parts are disposed on a first hypothetical line that is biasly located toward the pixel wiring side relative to a reference hypothetical line that passes through a position which makes an extending surface distance from pixel wiring and an extending surface distance from the signal input part equal to each other as well as on a second hypothetical line that is located biasly on the signal input part side relative to the reference hypothetical line.

8. The active matrix substrate according to claim 7, wherein the plural wirings have a wiring length that is made shorter toward the center side in the aligning direction thereof, and the plural connection parts are disposed on the first hypothetical line and the second hypothetical line so as to make the wiring resistance of the wirings become higher as the wiring length of the wirings becomes shorter.

9. The active matrix substrate according to claim 7, wherein the plural wirings have the wiring length thereof become shorter toward the center side in the aligning direction thereof and the plural connection parts are disposed so as to allow the first hypothetical line and the second hypothetical line to form straight lines.

10. The active matrix substrate according to claim 7, wherein the plural wirings are disposed so as to allow the first hypothetical line and the second hypothetical line to form curve lines respectively.

11. The active matrix substrate according to claim 7, wherein the plural wirings are disposed so that one of the wirings and the other wiring are alternately aligned.

12. The active matrix substrate according to claim 7, wherein the plural wirings are disposed so that a plurality of ones of wirings or the other wirings are successively disposed in parallel with one another.

13. The active matrix substrate according to claim 7, wherein the plural wirings include an array in which the one of wirings and the other wiring are adjacent with each other at least at one portion, and in the one of wrings and the other wiring that are adjacent to each other, the low resistance wiring part connected to the pixel wiring and the high resistance wiring part connected to the pixel wiring are respectively routed in a diagonal direction relative to the alignment direction such that the other end side relative to the one end side is biasly located on the center side in the aligning direction of the plural wirings, and the low resistance wiring part connected to the pixel wiring and the high resistance wiring part connected to the pixel wiring are disposed so as not to be overlapped with each other.

14. The active matrix substrate according to claim 7, wherein the plural wirings include an array in which the one of wirings and the other wiring are adjacent with each other at least at one portion, and in the one of wrings and the other wiring that are adjacent to each other, the low resistance wiring part connected to the pixel wiring and the high resistance wiring part connected to the pixel wiring are respectively routed in a diagonal direction relative to the alignment direction so that the other end side relative to the one end side is biasly located on the center side in the aligning direction of the plural wirings, and the low resistance wiring part connected to the pixel wiring and the high resistance wiring part connected to the pixel wiring are disposed so as to be overlapped with each other with an insulating film interposed therebetween.

15. The active matrix substrate according to claim 1, wherein the plural wirings are disposed in parallel with one another, and the low resistance wiring part or the high resistance wiring part connected to the pixel wiring is routed along a diagonal direction relative to the aligning direction such that the other end side relative to one end side is biasly located toward the center side relative to the aligning direction of the wirings, while the high resistance wiring part or the low resistance wiring part connected to the signal input part is routed linearly in a direction orthogonal to the aligning direction so that the one end side relative to the other end side is disposed at the same position relative to the aligning direction.

16. A display panel comprising:
the active matrix substrate according to claim 1; and
an opposing substrate bonded to the active matrix substrate.
